(19) United States
(12) Patent Application Publication
(10) Pub. No.: US 2009/0186230 A1
(43) Pub. Date: Jul. 23, 2009

(54) REFRACTORY METAL-DOPED SPUTTERING TARGETS, THIN FILMS PREPARED THEREWITH AND ELECTRONIC DEVICE ELEMENTS CONTAINING SUCH FILMS

(75) Inventors: Shuwei Sun, Framingham, MA (US); Mark Gaydos, Nashua, NH (US); Richard Wu, Chelmsford, MA (US); Prabhat Kumar, Framingham, MA (US)

Correspondence Address: CONNOLLY BOVE LODGE & HUTZ, LLP, P O BOX 2207, WILMINGTON, DE, 19899, US

(73) Assignee: H.C. Starck Inc., Newton, MA (US)

(21) Appl. No.: 12/256,609

(22) Filed: Oct. 23, 2008

Related U.S. Application Data
(60) Provisional application No. 60/982,163, filed on Oct. 24, 2007.

(51) Int. Cl. C23C 14/14; C23C 14/35; C23C 14/06; B22F 1/00

(52) U.S. Cl. 428/457; 204/298.13; 204/192.15; 204/192.11; 75/228; 75/246

(57) ABSTRACT

Metallic materials consisting essentially of a conductive metal matrix, preferably copper, and a refractory dopant component selected from the group consisting of tantalum, chromium, rhodium, ruthenium, iridium, osmium, platinum, rhenium, niobium, hafnium and mixtures thereof, preferably in an amount of about 0.1 to 6% by weight based on the metallic material, alloys of such materials, sputtering targets containing the same, methods of making such targets, their use in forming thin films and electronic components containing such thin films.

### CROSS-REFERENCE TO RELATED APPLICATIONS

This application claims priority to and benefit of, under 35 U.S.C. §119(e), U.S. Provisional Patent Application No. 60/982,163, filed on Oct. 24, 2007, the entire contents of which are hereby incorporated herein by reference.

### BACKGROUND OF THE INVENTION

Aluminum (Al) thin films are widely used in flat panel displays as conducting wires and electrodes. The substrate is normally glass (SiO₂, silicon dioxide). Copper (Cu) thin films are generally used in semiconductor integrated circuits for interconnect wires with silicon (Si) as a substrate. During normal device processing, the temperature can be raised to 250° C., and even as high as 500° C. At such temperatures, Al and Cu can diffuse into Si or SiO₂ substrates, and Si can likewise diffuse into the Al or Cu films. Hillocks, voids and other deleterious defects can form in the Al or Cu thin films and/or at the interfaces and impair the operability of the devices or circuits (e.g., short circuits).

In an effort to alleviate the problem of diffusion into Al and Cu films, a diffusion barrier layer, which can be molybdenum (Mo), tungsten (W), other refractory metals and/or their nitrides, can be deposited between the Al/Cu films and the substrate to reduce or eliminate the diffusion. The addition of an extra layer in the architecture of the device increases cost of materials, equipment and manpower and reduces throughput. Moreover, as the critical dimension employed in semiconductor IC fabrication continues to rapidly decrease to 45 nm, 32 nm and so on, the use of barrier layers will become prohibitive as spatial demands will not be able to be achieved.

Prior attempts to develop materials having both low diffusivity and low resistivity have included investigations of Mo- or W-doped Cu alloys. Attempts have been described to employ such materials as thin films for microdevice wirings and electrodes without the use of a barrier layer. Unfortunately, neither material has sufficient reduction in diffusivity and the necessary conductivity. While some molybdenum-doped copper materials can exhibit acceptable resistivity values, diffusion still occurs with an underlying silicon substrate to such a degree that a barrier layer is still necessary.

In addition to exhibiting high conductivity and low diffusion, suitable metallic materials for use as thin films in applications such as semiconductor interconnects, flat panel display wirings and the like should also have good thermal stability, high deposition rates, high etching rates, low stress and good adhesion to the substrate.

One technique used to produce metallic thin films in various manufacturing processes used in the semiconductor and the photoelectric industries is sputtering. The properties of films formed during sputtering are related to the properties of the sputtering target itself, such as the size of the respective crystal grain and the formation of secondary phase with distribution characteristics. It is desirable to produce a sputter target that will provide film uniformity, minimal particle generation during sputtering, and the desired electrical properties. Since sputtering is a common method of thin film formation, the metallic materials to be used as thin films in applications such as semiconductor interconnects, flat panel display wirings and the like should also be suitable for use as sputtering targets.

### BRIEF SUMMARY OF THE INVENTION

The present invention relates, in general, to metallic materials comprising a conductive matrix metal and one or more refractory metal dopants selected from a group including tantalum, chromium, rhodium, ruthenium, iridium, osmium, platinum, rhenium, niobium, hafnium, titanium, nickel and mixtures thereof; and particularly to such metallic materials for producing sputtering targets and sputtering targets comprising such materials. The one or more refractory metal dopants are preferably selected from a group including tantalum, chromium, rhodium, ruthenium, iridium, osmium, platinum, rhenium, niobium, hafnium, and mixtures thereof. Conductive matrix metals suitable for use in accordance with various embodiments of the present invention include copper and aluminum. In various preferred embodiments, the conductive matrix metal comprises copper. Metallic materials according to the various embodiments of the present invention can be used to prepare sputtering targets and alloys for a variety of uses including thin film formation and other metallization. Sputtering targets prepared from metallic materials of the present invention can be used to deposit thin films on substrates. Such thin films and their use in semiconductor components are encompassed by the present invention as well. Thin films provided by the invention can be used, for example, in semiconductor IC's, flat panel displays, optoelectronic devices, photovoltaic devices and solar cells as interconnects, conducting wires (e.g., data lines and address lines) and electrodes (e.g., gate, source and drain).

The metallic materials according to the various embodiments of the present invention can provide significantly improved properties related to subsequent processing of various electronic components which include thin films in accordance with the present invention. Applicants have surprisingly discovered that metallic materials in accordance with various embodiments of the present invention can provide useful thin films (e.g., preferably sputtered films) for electronics which offer significant advantages over the prior art, including, for example, a previously unknown combination of low resistivity and exceptional thermal stability accompanied by reduced mutual diffusion between the metallic material and a substrate (e.g., Si or SiO₂) upon which it has been deposited. Such a combination of advantageous properties affords a significant improvement over the prior art in that a material is provided which can be used to produce metallizations on dielectric substrates which have extremely high quality (e.g., capable of withstanding annealing without diffusion) and which exhibit excellent performance qualities (e.g., low resistivity). Metallic materials according to the various embodiments of the present invention can also exhibit excellent adhesion to various substrates when deposited as thin films in comparison to known materials.

Further remarkable and significantly advantageous is the discovery that the thin films according to the various embodiments of the present invention can be processed (e.g., annealed or otherwise subjected to heat) without the need for a barrier layer between the substrate and the thin film. Thus, the present invention offers a simplified replacement to the currently used conductive layer/diffusion barrier layer combination. The newly discovered materials which allow the omission of a barrier layer can entirely eliminate certain processing costs and/or simplify a variety of production operations resulting in significant cost savings.

One embodiment of the present invention includes metallic materials which consist essentially of a conductive matrix metal, preferably copper, and a refractory dopant component selected from the group consisting of tantalum, chromium, rhodium, ruthenium, iridium, osmium, platinum, rhenium, niobium, hafnium and mixtures thereof.

Another embodiment of the present invention includes metallic materials which consist essentially of a mixture of copper and tantalum, wherein the tantalum is preferably present in an amount of 0.1 to 6, and more preferably 2 to 4, percent by weight based on the metallic material.

Another embodiment of the present invention includes metallic materials which consist essentially of a mixture of copper and chromium, wherein the chromium is preferably present in an amount of 0.1 to 6, and more preferably 2 to 4, percent by weight based on the metallic material.

Another embodiment of the present invention includes metallic materials which consist essentially of a mixture of copper and a refractory dopant mixture of chromium and tantalum, wherein the refractory dopant mixture is preferably present in an amount of 0.1 to 6, and more preferably 2 to 4, percent by weight based on the metallic material. In such embodiments, the chromium and tantalum are each preferably present in an amount of 0.2 to 3, and more preferably 0.5 to 1.5, percent by weight based on the metallic material. In certain embodiments, the tantalum is preferably present in an amount of 1 percent by weight or less and the chromium is present in an amount of 0.5 percent by weight or less, based on the metallic material.

Another embodiment of the present invention includes sputtering targets which comprise a densified, homogenous powder mixture consisting essentially of a conductive matrix metal powder (preferably copper powder) and a refractory metal powder selected from the group of metal powders consisting of tantalum, chromium, rhodium, ruthenium, iridium, osmium, platinum, rhenium, niobium, hafnium and mixtures thereof.

Yet another embodiment of the present invention includes sputtering targets which can be prepared by a process comprising: (a) providing a homogenous powder mixture consisting essentially of a conductive matrix metal powder (e.g., copper powder) and a refractory metal powder selected from the group of powders consisting of tantalum, chromium, rhodium, ruthenium, iridium, osmium, platinum, rhenium, niobium, hafnium and mixtures thereof; and (b) subjecting the homogenous powder mixture to a thermo-mechanical method to form a sputtering target plate.

Other embodiments of the present invention include methods of preparing thin films, and the thin films prepared thereby, which methods comprise: (a) providing a substrate; (b) providing a sputtering target according to one or more other embodiments of the present invention; and (c) subjecting the sputtering target to a source of energy such that a thin film comprised of the sputtering target material is disposed on a surface of the substrate. Another embodiment of the present invention includes thin films comprising a metallic material consisting essentially of copper and a refractory metal dopant selected from the group consisting of tantalum, chromium, rhodium, ruthenium, iridium, osmium, platinum, rhenium, niobium, hafnium and mixtures thereof.

Yet another embodiment of the present invention includes semiconductor devices comprising a substrate and a thin film disposed on a surface of the substrate, wherein the thin film consists essentially of copper and a refractory dopant having a concentration of about 0.1 to 6 percent by weight based on the thin film, and wherein the refractory dopant comprises a metal selected from the group consisting of tantalum, chromium, rhodium, ruthenium, iridium, osmium, platinum, rhenium, niobium, hafnium and mixtures thereof.

Other embodiments of the present invention include metallic materials, sputtering targets prepared therefrom, methods of depositing thin films with such targets, the thin films formed thereby and semiconductor, flat panel display, and solar cell devices containing such thin films, wherein the metallic materials consist essentially of a conductive matrix metal, preferably copper, and titanium or nickel. In such embodiments, the titanium or nickel is preferably present in an amount of 0.1 to 6 percent by weight based on the metallic material, more preferably 1 to 3 percent by weight.

In certain preferred embodiments of the invention, the refractory dopant component can be segregated into grain boundaries likely due to the relative insolubility of the refractory metals in the conductive matrix metal, particularly Cu. Grain boundaries are diffusion channels in materials, where defects and vacancies are more prevalent than within the grains. Vacancy diffusion is widely presumed to be the most important mechanism for diffusion. Refractory metal atoms present at grain boundaries can thus help block the diffusion channels and reduce diffusion. Additionally, resistivity remains low since the refractory dopant component is present in a small quantity.

### BRIEF DESCRIPTION OF THE SEVERAL VIEWS OF THE DRAWING

The foregoing summary, as well as the following detailed description of the invention, will be better understood when read in conjunction with the appended drawings. For the purpose of illustrating the invention, there is shown in the drawings, embodiments which are presently preferred. It should be understood, however, that the invention is not limited to the precise arrangements and instrumentalities shown.

In the Figs.:

FIG. 1a is a cross-sectional representation of a prior art bilayer conducting line having a barrier layer in an electronic component;

FIG. 1b is a cross-sectional representation of a conducting line in accordance with an embodiment of the present invention;

FIG. 2a is a graphical representation (Auger profile) at various annealing temperatures of a Cu—Ta film in accordance with an embodiment of the invention as a function of film depth;

FIG. 2b is a graphical representation (Auger profile) at various annealing temperatures of a copper film in accordance with a control example as a function of film depth;

FIG. 2c is a graphical representation (Auger profile) at various annealing temperatures of a Cu—Ta/Cr film in accordance with an embodiment of the invention as a function of film depth;

FIG. 2d is a graphical representation (Auger profile) at various annealing temperatures of a Cu—Ni film in accordance with an embodiment of the invention as a function of film depth;

FIG. 3a is a graphical overlay of Auger profiles at various annealing temperatures of the film represented in FIG. 2a;

FIG. 3b is a graphical overlay of Auger profiles at various annealing temperatures of the copper film represented in FIG. 2b;

FIG. 3c is a graphical overlay of Auger profiles at various annealing temperatures of the film represented in FIG. 2c;

FIG. 3d is a graphical overlay of Auger profiles at various annealing temperatures of the film represented in FIG. 2d;

FIG. 4 is a graphical representation (Auger profile) at various annealing temperatures of a copper-molybdenum film in accordance with a comparative example as a function of film depth;

FIG. 5 is a graphical representation of resistivity as a function of annealing temperature for various films;

FIGS. 6a, 6b, 6c and 6d are SEM images of a copper-tantalum film in accordance with an embodiment of the invention at various annealing temperatures;

FIGS. 7a, 7b, 7c and 7d are SEM images of a copper film in accordance with a control example at various annealing stages;

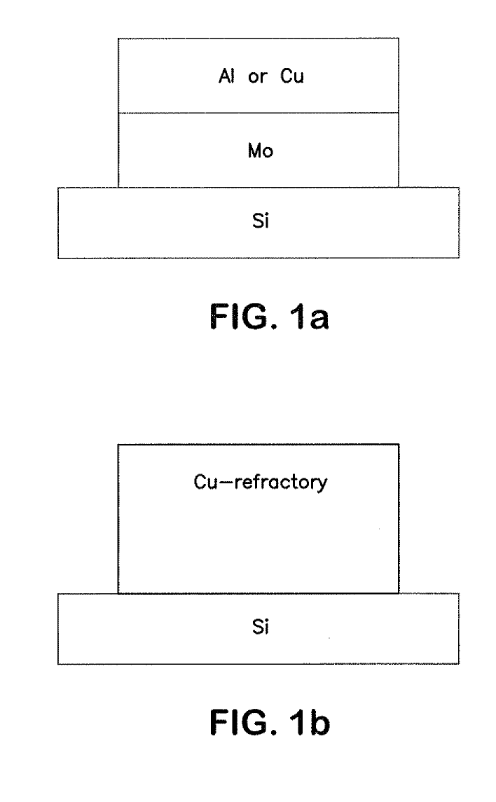

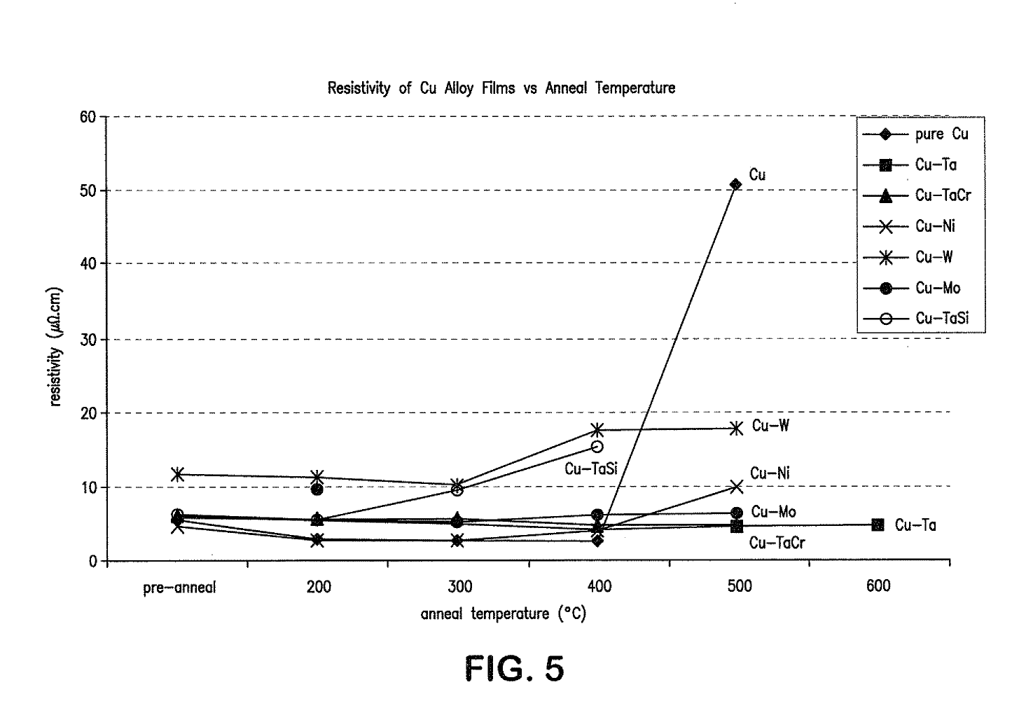

FIG. 5a is a set of x-ray diffraction spectra of a copper-tantalum film in accordance with an embodiment of the invention under various annealing conditions;

FIG. 8b is a set of x-ray diffraction spectra of a copper-tantalum/chromium film in accordance with an embodiment of the invention under various annealing conditions;

FIG. 5c is a set of x-ray diffraction spectra of a copper-nickel film in accordance with an embodiment of the invention under various annealing conditions;

FIG. 8d is a set of x-ray diffraction spectra of a copper film in accordance with a control example under various annealing conditions;

FIG. 9a is a set of x-ray diffraction spectra of a copper-molybdenum film in accordance with a comparative example under various annealing conditions; and

FIG. 9b is a set of x-ray diffraction spectra of a copper-tungsten film in accordance with a comparative example under various annealing conditions.

### DETAILED DESCRIPTION OF THE INVENTION

As used herein, the singular terms “a” and “the” are synonymous and used interchangeably with “one or more” or “at least one.” Accordingly, for example, reference to “a metal” herein or in the appended claims can refer to a single metal or more than one metal.

As used herein, with reference to those embodiments of the invention containing a refractory dopant component selected from the group consisting of tantalum, chromium, rhodium, ruthenium, iridium, osmium, platinum, rhenium, niobium, hafnium and mixtures thereof, the phrases “consisting essentially of” and “consist(s) essentially of” refer to the recited inventive elements which follow the phrases in an open-ended manner according to the normally accepted understanding of the term “comprising,” except that the aforementioned phrases exclude the presence of elemental aluminum, silver, gold, titanium, nickel, cobalt, silicon, or combinations thereof added in amounts of 0.1 to 3.0% by weight to improve conductivity. The phrases do not carry any other limiting effect aside from the preclusion of those additional elements which would affect the basic and novel characteristics of the invention.

As used herein, with reference to those embodiments of the invention containing a conductive matrix metal, and titanium or nickel, the phrases “consisting essentially of” and “consist(s) essentially of” refer to the recited inventive elements which follow the phrases in an open-ended manner according to the normally accepted understanding of the term “comprising,” except that the aforementioned phrases exclude the presence of elemental tungsten and molybdenum, or combinations thereof. The phrases do not carry any other limiting effect aside from the preclusion of those additional elements which would affect the basic and novel characteristics of the invention.

Metallic materials in accordance with various embodiments of the present invention comprises mixtures of metals. The mixtures are primarily based on a conductive matrix metal, preferably copper. In various preferred embodiments, the metal materials comprise a major portion of a conductive matrix metal. More preferably, the metal materials comprise greater than 90% by weight of a conductive matrix metal, more preferably at least about 94% by weight of a conductive matrix metal, and most preferably about 97 to 99% by weight of a conductive matrix metal. In each case, the conductive matrix metal preferably comprises copper. More preferably the conductive matrix metal is copper.

In various particularly preferred embodiments, the metallic materials according to the invention comprise a mixture of a conductive matrix metal, preferably copper, and a refractory dopant component as described below, and exclude any other metals in other than negligible amounts. In other words, certain particularly preferred embodiments of metal materials according to the present invention contain copper and a refractory metal dopant, with only trace additional elements, and even more preferably no trace elements.

Suitable refractory dopant components include tantalum, chromium, rhodium, ruthenium, iridium, osmium, platinum, rhenium, niobium, hafnium and mixtures thereof. Preferred refractory dopant components include tantalum, chromium and mixtures thereof. In certain particularly preferred embodiments of the invention, the refractory dopant comprises tantalum, and more preferably consists of tantalum. In certain other particularly preferred embodiments of the invention, the refractory dopant comprises chromium, and more preferably consists of chromium. In certain other particularly preferred embodiments of the invention, the refractory dopant comprises chromium and tantalum, and more preferably consists of chromium and tantalum.

In metallic materials, mixtures, alloys, sputtering targets and thin films according to the various embodiments of the invention, the refractory dopant component is present in a small quantity, e.g., less than about 7.5% by weight. Preferably, the refractory dopant component is present in an amount of about 0.1 to about 6% by weight, based on the metallic material, mixture, alloy, target or film. More preferably, the refractory dopant component is present in an amount of about 1 to about 3% by weight. In particularly preferred embodiments, the refractory dopant component is present in an amount of 2.0+/−1.0% by weight.

A metallic material according to the present invention may exist in various forms, such as, for example, a powder blend, a densified target, or an alloy in any physical state. Powder blends can be advantageous for homogenizing the constituent metals prior to metallurgical processing to form sputtering targets.

Sputtering targets in accordance with the present invention can be prepared, for example, by combining a copper metal powder and a refractory dopant metal powder, mixing the powders, and subjecting the mixed powders to metallurgical processing, which may include, for example, compaction, sintering, and/or densification, etc.

Thus, in various embodiments of the present invention, a suitable powder blend for preparation of targets according to the invention can be prepared by combining an appropriate copper powder and a refractory dopant metal powder. Metal powders suitable for use in the present invention can be atomized in any appropriate manner, for example, by water or gas. Powders suitable for use in the present invention preferably have a purity of 99.95% (“3N5”) or higher, more preferably 99.99% (“4N”) or higher, and most preferably 99.999% (“5N”) or higher.

Preferably, a conductive matrix metal powder will have an average particle size of 20 μm. Preferably, a refractory metal dopant powder average particle size is as small as possible. Generally, the refractory metal dopant powder is no larger in average particle size than the conductive matrix metal powder. For example, a tantalum powder can have an average particle size of 15 μm or less.

The copper powder and the refractory dopant metal powder are combined and mixed. The metal powders can be mixed using any powder blending techniques known in the art. For example, mixing may occur by placing the metal powders in a dry container and rotating the container about its central axis. Mixing can be continued for a period of time sufficient to result in a homogenous blend, i.e., a uniformly distributed powder. A ball mill or similar apparatus may also be used to accomplish the blending step. The invention is not limited to any particular mixing technique, and other mixing techniques may be chosen if they will sufficiently blend the metal powders to achieve suitable homogeneity.

The blended powders according to the various embodiments of the invention described above can then be subjected to one or more of a variety of metallurgical processes to provide sputtering targets in accordance with various embodiments of the present invention. Suitable metallurgical processing can include compaction, sintering, rolling and combinations thereof.

For example, a blended powder can optionally be consolidated in a preliminary compacting step to a green density of about 70 to 80% of theoretical density. The consolidation can be accomplished by any means known to one skilled in the art of powder metallurgy, such as by cold isostatic pressing, rolling or die compaction. The length of time and amount of pressure used will vary depending on the degree of consolidation desired to be achieved in this step. For some types of targets, such as tubular targets, this step may not be necessary.

Following a preliminary consolidation step the consolidated powder can be encapsulated. Encapsulation can be accomplished by any method that will provide a compact work piece that is free of interconnected surface porosity, such as by sintering, thermal spraying, canning, and the like. As used herein, the term “encapsulation” refers to any method known in the art for providing the compact piece free of interconnected surface porosity. Preferably, a compacted powder mixture is subjected to sintering. Particularly preferred sintering can be carried out in two stages in dissociated ammonia for about 40-45 minutes at about 700° C. to 750° C. In various preferred embodiments, sintering can comprises two stages. In a first stage, sintering can be carried out at 600 to 700° C. for 20 to 30 minutes. The second stage can be carried out at 1000 to 1050° C. for 20 to 30 minutes. Various embodiments may also include a room temperature pressing between the first and second sintering stages at pressures of 35 to 45 tons per square inch.

After encapsulation, the encapsulated metallic material can be compacted under heat and pressure. Various compacting methods are known in the art, including, but not limited to, methods such as inert gas uniaxial hot pressing, vacuum hot pressing, and hot isostatic pressing, and rapid omnidirectional compaction. Preferably, the encapsulated piece is hot isostatically pressed into the desired target shape. Hot isostatic pressing can be carried out using any combination of operational parameters known in the art, e.g., under pressure of 5,000 to 20,000 psi (˜34.5 to 138 MPa), more preferably 10,000 to 15,000 psi (˜69 to 103 MPa), at temperatures of 700 to 1000° C., more preferably 800 to 900° C., for a period of 2 to 8 hours, more preferably 3 to 5 hours. Other methods of hot pressing can be used to produce the sputtering targets of the present invention, so long as the appropriate temperature, pressure and time conditions are maintained.

After the final compaction step the target plate can be machined to the desired size and shape, and optionally bonded to a backing plate, as is known in the art, to produce the final sputtering target. When a larger sputter target is desired, two or more target plates of the present invention can be bonded together in an edge-to-edge fashion.

Finished sputtering targets of the present invention can have a density of greater than about 90% theoretical density, preferably at least 95% of theoretical density, and more preferably at least 98%.

The present invention also includes methods of forming thin films comprised of a metallic material according to any of the various metallic material embodiments of the invention. Suitable methods for forming thin films according to the present invention include physical vapor deposition and electroplating of a metallic material according to an embodiment of the invention. In various preferred methods of the present invention, the physical vapor deposition comprises sputtering.

The present invention also includes the use of sputtering targets according to the various embodiments described above to prepare thin films. Accordingly, in various embodiments of the present invention, a sputtering target according to an embodiment of the invention is subjected to a sputtering method to provide a thin film on a substrate.

Sputtering in accordance with various particularly preferred embodiments of the present invention comprises DC magnetron sputtering. Any suitable DC magnetron sputtering system and/or method known in the art, or to be developed can be used to sputter a thin film using a sputtering target according to the various embodiments of the present invention.

In various particularly preferred embodiments, a DC magnetron sputtering process can be carried out under conditions which include: a source power of 100 W to 2000 W, more preferably 100 W, e.g., for a small 2.5″ diameter target; a sputter pressure of 1 mTorr to 20 mTorr, more preferably at about 10 mTorr, using an Argon-containing plasma; a distance between target and substrate of about 2.5 to 20 cm, more preferably about 5-10 cm; a substrate bias of 0V to −300V, more preferably 0V; and a substrate temperature of room temperature to 500° C., more preferably about room temperature.

Suitable substrates upon which a thin film according to the invention can be deposited can include any material which can be used in electronic applications and which can suitable withstand PVD and/or electroplating conditions. Preferable substrates can include silicon materials or any other insulating material employed in electronic applications, such as, for example, single crystalline Si, amorphous Si, glass, silica, or a substrate coated with a layer of amorphous Si or SiO₂. The thickness of such SiO₂ coating layers can be 20 nm to 300 nm, more preferably about 30 nm.

The present invention also includes thin films comprising a metallic material according to the various embodiments of the invention. As described above, such thin films are preferably provided by sputtering a target according to an embodiment of the invention. Thin films in accordance with the present invention can have a thickness of 5 nm to 500 nm, preferably 100 nm to 200 nm, and more preferably about 100 nm.

Thin films in accordance with the present invention preferably have a nanocrystalline microstructure with an average grain size of 20 to 100 nm. More preferably, the average grain size can be about 70 to 90 nm, and most preferably about 80 nm. Average grain size can be determined in accordance with known methods using, for example, SEM imaging detection.

In various particularly preferred embodiments of the present invention, a thin film comprises a binary alloy of copper and a refractory dopant selected from the group consisting of tantalum, chromium, and mixtures thereof in an amount of 0.1 to 6% by weight, based on the film, preferably wherein the film has an average grain size of about 80 nm.

The present invention also includes electronic devices, preferably semiconductor integrated circuits and LCD display panel circuit devices, including for example, thin-film transistors, in which the device includes a thin film according to an embodiment of the invention disposed on a substrate. Thin films for use in electronic devices according to the invention can be deposited in accordance with the methods described herein, for example, by sputtering. Prior to further processing of such electronic devices (e.g., etching, etc.), the thin film can encounter high temperature processes and can therefore be annealed. Thin films in accordance with the present invention can be annealed at temperatures and under conditions normally encountered in the processing of such electronic devices without exhibiting harmful diffusion into the underlying substrate. Suitable annealing can be carried out, for example, at temperatures of about 200° C. to 600° C. for about 2 hours, in an oven, such as a vacuum oven at a base pressure of about 5×10⁻⁸ Torr.

The invention will now be described in further detail with reference to the following non-limiting examples.

### EXAMPLES

### Control, Examples 1-4 and Comparative Examples 5-7

### Thin Film Evaluation

Initially, a copper powder was provided (Control Sample, Pure Cu) and seven powders were prepared (Inventive Example 1, Cu—Ta; Inventive Example 2, Cu—Cr; Inventive Example 3, Cu—Ta/Cr; Inventive Example 4, Cu—Ni; and Comparative Examples 5, 6 & 7, Cu—Mo, Cu—W and Cu—Ta/Si, respectively) by dry blending copper powder, CuLox® type 620, normal 20 μm (commercially available from CuLox Technologies, Inc., Naugatuck, Conn.), with Ta, Cr, Ni, Si, Mo and/or W powder, as designated above, in amounts of 0.1 to 6% by weight. The tantalum powder used was H. C. Starok NH230 capacitor grade powder, available from H. C. Starck, Inc. Newton, Mass.). The chromium powder used was 325-mesh powder commercially available from Alfa/Aesar. The molybdenum powder used was H. C. Starek type MMP-OMFP, normal 5 μm, available from H. C. Starok, Inc. (Newton, Mass.). The tungsten powder used was H. C. Starck WMP normal 3.5 μm, available from H. C. Starok, Inc. (Newton, Mass.). The nickel powder used was 99.8% Ni, Catalog No. 44739-36, CC0501 (−150/+200 mesh), available from Alfa Aesar. The silicon-doped tantalum powder used was H. C. Starck TPX (−325 mesh), available from H. C. Starck, Inc. (Newton, Mass.).

The powders were blended using a V-blender, and mechanically compacted to form disks approximately 060 mm by 10 mm thick, having a 73% to 77% green density. The green compacts were then each partially sintered in dissociated ammonia for about 40 to 45 minutes at 705° to 730° C. The partially sintered disks were each coined using a load of 45 tons and sintered in dissociated ammonia for 30 to 35 minutes at 1040° to 1055° C. Full densification of the sintered disks was ensured by hot isostatic pressing (HIP) for four hours at 10,000 psi (˜69 MPa) at 750° C. Each disk was machined to Ø 51 mm. by 6.35 mm thick. The resulting targets were then used to prepare thin films for evaluation.

The thin films were deposited on single crystal silicon wafer (100) and Corning 1737 glass wafers via DC magnetron sputtering. The sputtering was carried out at a power of 100 W, a pressure of 10 millitorr using Argon as media, at a distance between target and substrate of about 3 inches; with a substrate bias of 0V, and a substrate temperature at about room temperature. The sputter chamber was made by CSM Model LEXUS.

Four thin films were prepared from each target for annealing. The resulting thin films had a thickness of 200 nm upon deposition. Each thin film was annealed for 2 hours at 200°, 300°, 400° and 500° C. (unless indicated otherwise below), respectively, in a vacuum oven with base pressure 5×10⁻⁰⁸ Torr.

The thin films were then evaluated using Auger electron spectroscopy (AES), transmitting electron microscopy (TEM), scanning electron microscopy (SEM), X-ray diffraction (XRD), and a 4-point probe, before and after annealing. AES provides diffusion profile measurements of Cu, Si and other elements in thin films deposited on a substrate over the entire depth of the film and into the substrate, as well as at the interface of the film and substrate. TEM provides a measurement of refractory metal atom segregation at grain boundaries. SEM provides a measurement of thin film microstructure (e.g., grain size) changes before and after annealing. XRD provides a measurement of crystal structure changes before and after annealing. 4-point probe measurements provide resistivity change before and after annealing.

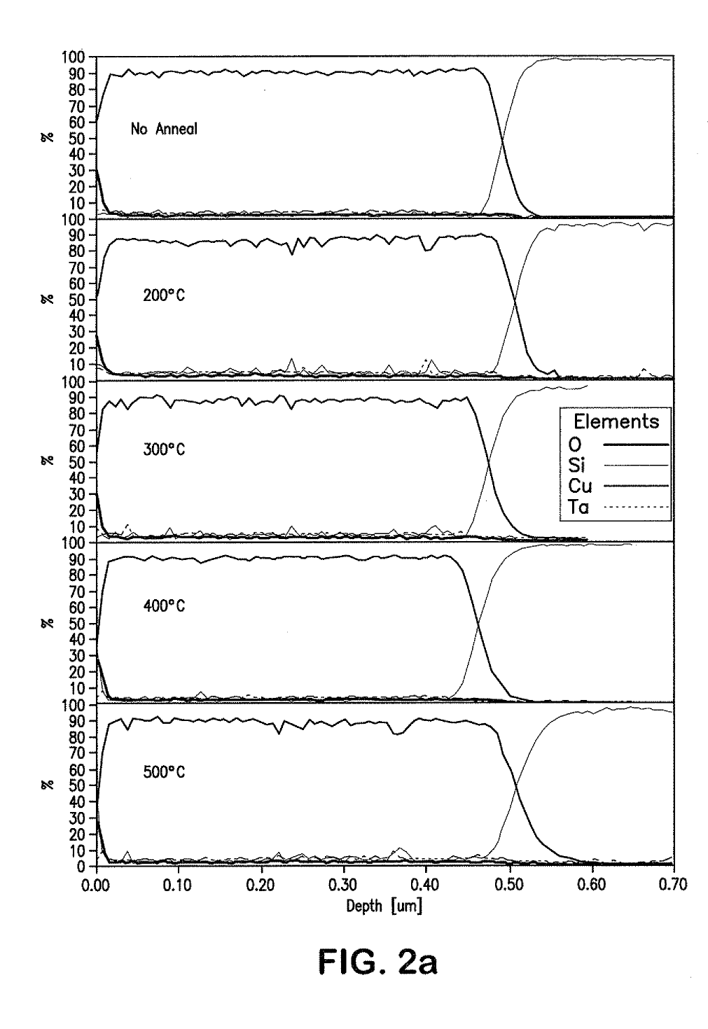

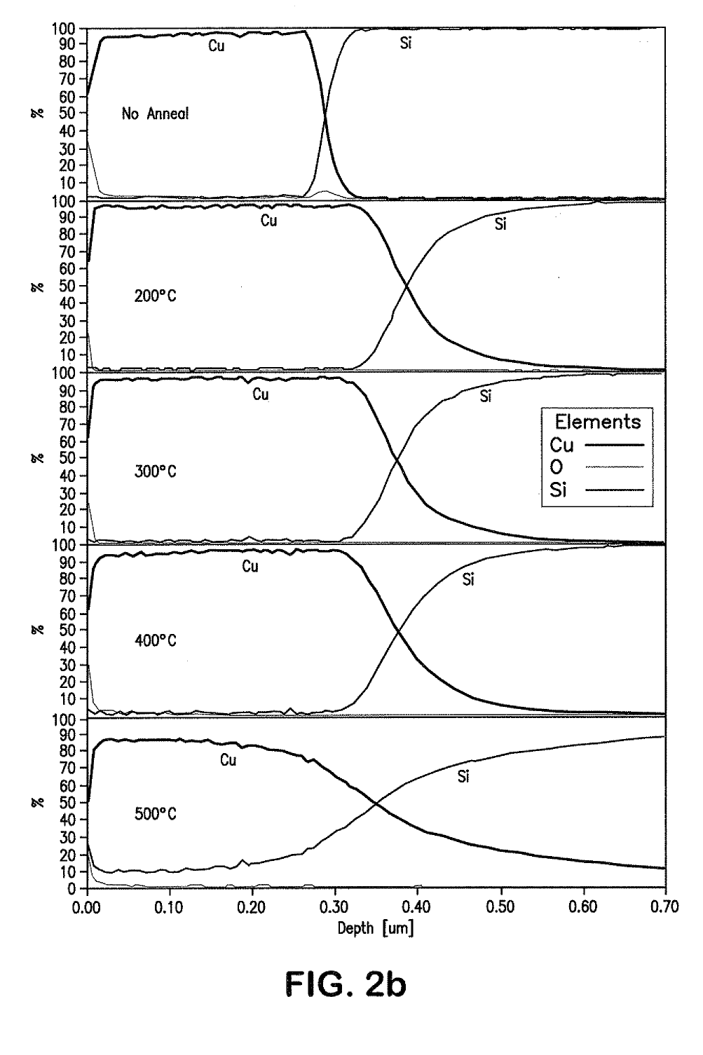

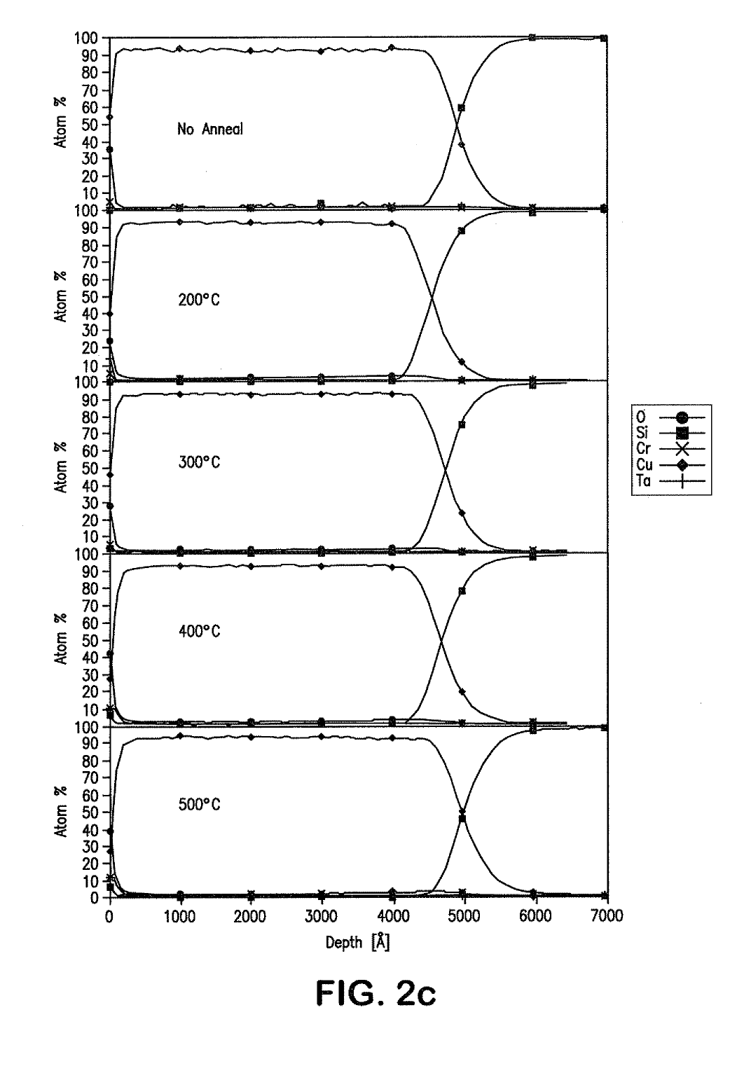

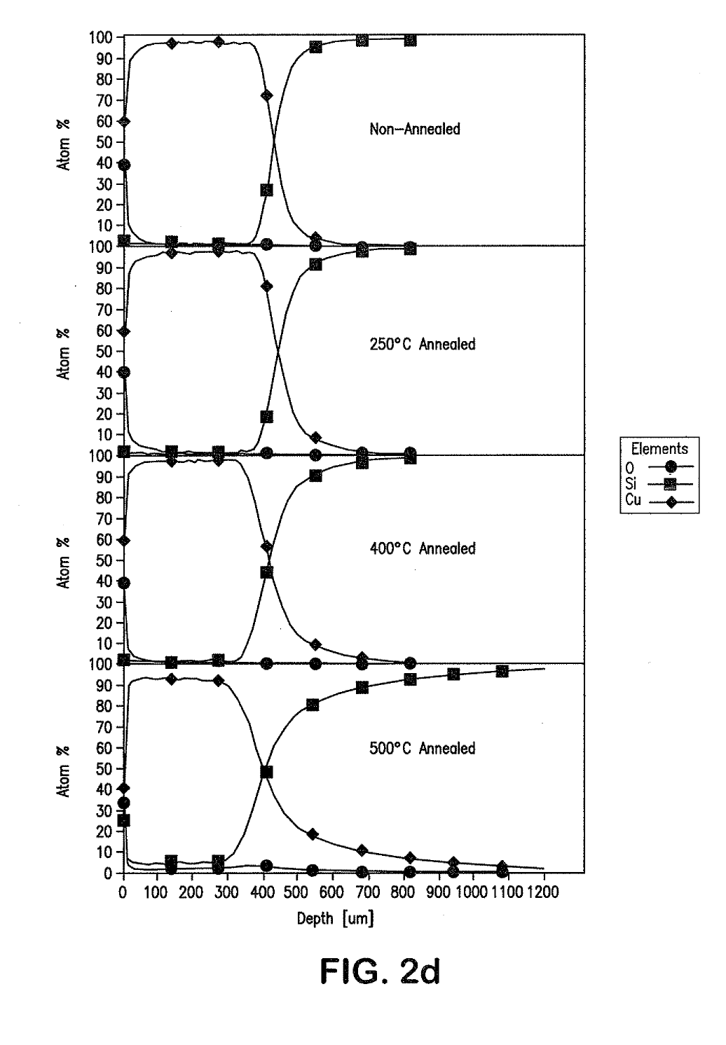

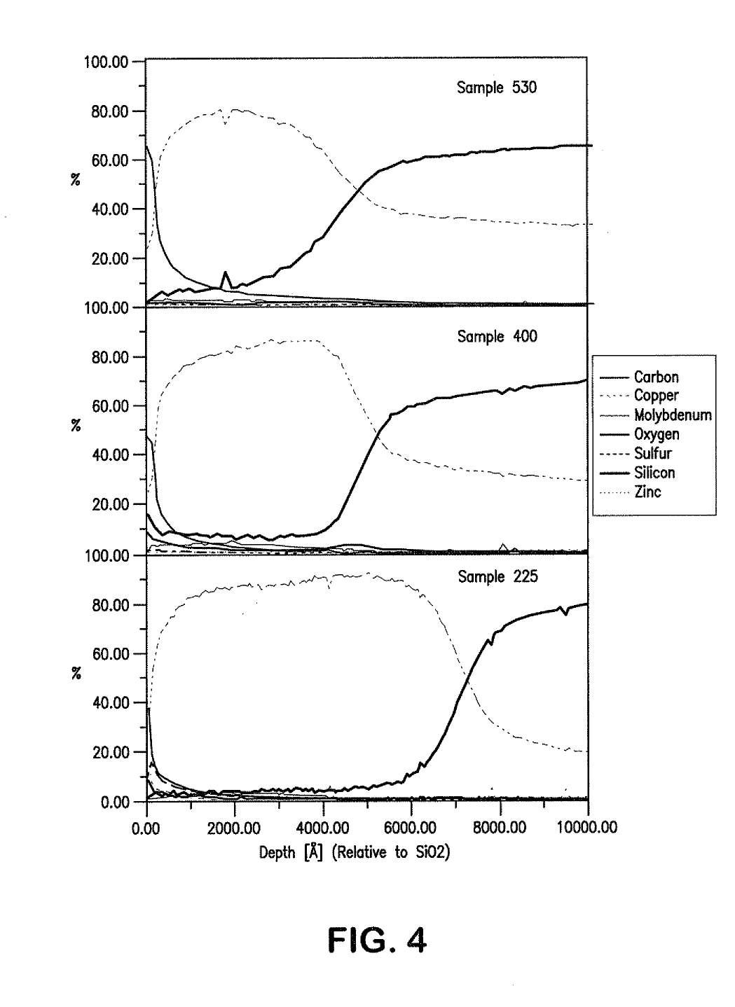

Each of the tantalum-doped copper thin film (Cu—Ta) of Example 1, the chromium-doped copper thin film (Cu—Cr) of Example 2, and the tantalum/chromium-doped copper thin film (Cu—Ta/Cr) of Example 3, exhibited a lower diffusivity than the Control thin film (pure Cu) and the molybdenum-doped copper thin film of Comparative Example 5 (Cu—Mo), as detected by Auger electronic spectroscopy (AES). The interface of the Cu—Ta film and Si substrate was virtually unchanged when annealed up to 500° C. for 2 hours, indicating almost no diffusion, or only negligible diffusion. A similar lack of diffusion was exhibited by the Cu—Ta/Cr film and Si substrate. In contrast, the interface of the Si substrate and the pure Cu Control film became widely diffused when annealed at only 200° C. for 2 hours, indicating substantial mutual diffusion. The diffusion was severe when annealed at 500° C. for 2 hours as shown below in Tables 2a, 2b and 2c and FIGS. 2a, 2b and 2c. Similarly, the interface of the Si substrate and the molybdenum-doped copper film of Comparative Example 5 became widely diffused when annealed at only 200° C. for 2 hours, indicating substantial mutual diffusion. The diffusion was also severe when annealed at 500° for 2 hours as shown below in Table 4 and FIG. 4.

As shown below in Tables 2a and 2c, the Cu—Ta film of Example 1 and the Cu—Ta/Cr film of Example 3 exhibit almost no diffusion of Cu and Si after annealing up to 500° C. for 2 hours. However, as contrasted in Table 2b, also below, diffusion of Cu and Si in the pure Cu film of the Control sample is significant after annealing at only 200° C. for 2 hours. Diffusion in the Control sample is severe after annealing at 500° C. This can be seen in Tables 2a, 2b and 2c, by comparing the percent content of copper (Cu) and silicon (Si), at 500° C. anneal for example, near the 0 μm Distance to Interface. For example, in the Cu—Ta film of Example 1 shown in Table 2a, at −0.02 mm from the interface, the percent content of copper far exceeds that of silicon, whereas at the same distance from the interface in the copper only film of the Control sample, the percent content of silicon is 42% and copper is 53%. This indicates significant diffusion in the Control sample.

As shown below in Table 2d, the Cu—Ni film of Example 4 exhibits less diffusion of Cu and Si after annealing up to 500° C. for 2 hours in comparison to the Control Sample and the Comparitive Examples.

TABLE 2a
Cu—Ta Thin Film (Example 1).

| Distance | Pre-Anneal | | 200° C. | | 300° C. | | 400° C. | | 500° C. | |
|---|---|---|---|---|---|---|---|---|---|---|
| to interface | Cu | Si | Cu | Si | Cu | Si | Cu | Si | Cu | Si |
| (μm) | (%) | (%) | (%) | (%) | (%) | (%) | (%) | (%) | (%) | (%) |
| −0.20 | 90 | 6 | 88 | 7 | 87 | 5 | 90 | 5 | 90 | 5 |
| −0.18 | 90 | 5 | 88 | 8 | 87 | 5 | 92 | 5 | 88 | 4 |
| −0.16 | 92 | 6 | 84 | 10 | 87 | 4 | 92 | 6 | 88 | 4 |
| −0.14 | 92 | 5 | 88 | 6 | 88 | 6 | 89 | 6 | 82 | 3 |
| −0.12 | 91 | 5 | 90 | 6 | 86 | 7 | 90 | 6 | 88 | 5 |
| −0.10 | 90 | 5 | 82 | 11 | 86 | 2 | 92 | 6 | 90 | 5 |
| −0.08 | 92 | 4 | 90 | 4 | 85 | 6 | 91 | 7 | 88 | 5 |
| −0.06 | 92 | 4 | 91 | 4 | 85 | 8 | 91 | 7 | 88 | 5 |
| −0.05 | 91 | 5 | 89 | 8 | 86 | 6 | 91 | 6 | 88 | 4 |
| −0.04 | 93 | 4 | 92 | 4 | 86 | 6 | 93 | 7 | 87 | 7 |
| −0.035 | 92 | 4 | 88 | 2 | 88 | 5 | 92 | 7 | 88 | 7 |
| −0.03 | 91 | 4 | 86 | 6 | 88 | 5 | 90 | 6 | 87 | 9 |
| −0.025 | 89 | 4 | 86 | 7 | 87 | 4 | 89 | 6 | 85 | 11 |
| −0.02 | 84 | 8 | 84 | 8 | 81 | 7 | 85 | 10 | 80 | 18 |
| −0.015 | 75 | 14 | 77 | 19 | 75 | 11 | 80 | 12 | 69 | 26 |
| −0.01 | 66 | 25 | 69 | 26 | 68 | 24 | 72 | 20 | 64 | 31 |
| −0.005 | 57 | 39 | 58 | 31 | 59 | 36 | 61 | 32 | 57 | 40 |
| 0 | 47 | 47 | 48 | 48 | 47 | 47 | 50 | 50 | 49 | 49 |
| 0.005 | 41 | 58 | 38 | 58 | 38 | 55 | 45 | 54 | 41 | 56 |
| 0.01 | 32 | 66 | 30 | 66 | 35 | 60 | 36 | 60 | 36 | 61 |
| 0.015 | 24 | 76 | 21 | 75 | 28 | 70 | 30 | 67 | 31 | 68 |
| 0.02 | 15 | 84 | 14 | 82 | 22 | 77 | 24 | 76 | 25 | 71 |
| 0.025 | 10 | 88 | 11 | 86 | 17 | 80 | 18 | 81 | 21 | 78 |
| 0.03 | 7 | 91 | 9 | 90 | 10 | 84 | 15 | 82 | 16 | 81 |
| 0.035 | 5 | 94 | 6 | 92 | 9 | 86 | 12 | 87 | 13 | 85 |
| 0.04 | 3 | 96 | 7 | 93 | 6 | 91 | 9 | 91 | 12 | 87 |
| 0.05 | 2 | 96 | 6 | 91 | 4 | 92 | 4 | 95 | 8 | 92 |
| 0.06 | 2 | 97 | 2 | 97 | 4 | 94 | 3 | 97 | 4 | 94 |
| 0.08 | 2 | 97 | 2 | 96 | 4 | 94 | 1 | 98 | 5 | 94 |
| 0.10 | 1 | 98 | 2 | 97 | 4 | 95 | 1 | 98 | 2 | 95 |
| 0.12 | 2 | 98 | 2 | 96 | 4 | 95 | 1 | 98 | 6 | 96 |
| 0.16 | 2 | 98 | 2 | 96 | — | — | 1 | 98 | 5 | 96 |
| 0.20 | 2 | 98 | 3 | 97 | — | — | 1 | 98 | 8 | 96 |

TABLE 2b
Pure Cu Thin Film (Control Sample).

| Distance | Pre-Anneal | | 200° C. | | 300° C. | | 400° C. | | 500° C. | |
|---|---|---|---|---|---|---|---|---|---|---|
| to Interface | Cu | Si | Cu | Si | Cu | Si | Cu | Si | Cu | Si |
| (μm) | (%) | (%) | (%) | (%) | (%) | (%) | (%) | (%) | (%) | (%) |
| −0.20 | 95 | 2 | 98 | 1 | 97 | 1 | 96 | 1 | 84 | 13 |
| −0.18 | 96 | 1 | 97 | 2 | 97 | 2 | 96 | 2 | 84 | 13 |
| −0.16 | 96 | 1 | 98 | 2 | 97 | 2 | 96 | 2 | 83 | 15 |
| −0.14 | 97 | 1 | 98 | 1 | 96 | 2 | 96 | 2 | 82 | 17 |
| −0.12 | 96 | 2 | 96 | 2 | 96 | 2 | 97 | 2 | 80 | 18 |
| −0.10 | 97 | 2 | 97 | 2 | 96 | 2 | 97 | 1 | 78 | 19 |
| −0.08 | 97 | 1 | 98 | 2 | 96 | 1 | 97 | 2 | 74 | 22 |
| −0.06 | 97 | 1 | 94 | 4 | 95 | 2 | 94 | 3 | 68 | 29 |
| −0.05 | 95 | 1 | 91 | 4 | 93 | 4 | 90 | 9 | 63 | 32 |
| −0.04 | 96 | 2 | 86 | 12 | 87 | 9 | 84 | 16 | 60 | 34 |
| −0.035 | 97 | 5 | 80 | 14 | 84 | 12 | 77 | 19 | 59 | 36 |
| −0.03 | 97 | 7 | 76 | 22 | 80 | 16 | 73 | 22 | 58 | 38 |
| −0.025 | 97 | 11 | 72 | 26 | 76 | 21 | 70 | 26 | 57 | 40 |
| −0.02 | 92 | 14 | 68 | 28 | 70 | 26 | 64 | 32 | 53 | 42 |
| −0.015 | 88 | 19 | 64 | 34 | 66 | 32 | 61 | 36 | 52 | 43 |
| −0.01 | 86 | 29 | 60 | 40 | 62 | 36 | 58 | 40 | 51 | 44 |
| −0.005 | 65 | 40 | 55 | 44 | 55 | 40 | 54 | 45 | 50 | 47 |
| 0 | 48 | 48 | 50 | 50 | 49 | 49 | 49 | 49 | 49 | 49 |
| 0.005 | 42 | 56 | 46 | 52 | 45 | 51 | 45 | 53 | 48 | 50 |
| 0.01 | 28 | 70 | 40 | 59 | 43 | 54 | 42 | 55 | 47 | 51 |
| 0.015 | 18 | 79 | 38 | 62 | 40 | 56 | 39 | 58 | 45 | 53 |
| 0.02 | 14 | 84 | 34 | 64 | 36 | 61 | 35 | 62 | 41 | 54 |
| 0.025 | 10 | 90 | 32 | 67 | 32 | 66 | 33 | 64 | 40 | 55 |
| 0.03 | 6 | 95 | 30 | 71 | 30 | 68 | 32 | 66 | 39 | 56 |
| 0.035 | 4 | 97 | 27 | 74 | 28 | 70 | 29 | 70 | 38 | 57 |
| 0.04 | 3 | 98 | 24 | 76 | 25 | 72 | 23 | 72 | 37 | 60 |
| 0.05 | 2 | 97 | 19 | 80 | 22 | 77 | 21 | 77 | 36 | 61 |
| 0.06 | 2 | 97 | 17 | 82 | 19 | 80 | 18 | 80 | 33 | 63 |
| 0.08 | 2 | 99 | 12 | 86 | 13 | 84 | 16 | 85 | 30 | 68 |
| 0.10 | 2 | 98 | 10 | 90 | 10 | 89 | 9 | 90 | 26 | 70 |
| 0.12 | 2 | 99 | 6 | 92 | 8 | 90 | 10 | 92 | 25 | 72 |
| 0.16 | 2 | 98 | 4 | 96 | 5 | 95 | 6 | 94 | 22 | 75 |
| 0.20 | 2 | 98 | 3 | 98 | 3 | 97 | 4 | 95 | 20 | 79 |
| 0.24 | 2 | 98 | 2 | 99 | 2 | 98 | 2 | 97 | 18 | 81 |

TABLE 2c
Cu—TaCr Thin Film (Example 3).

| Distance | Pre-anneal | | 200° C. | | 300° C. | | 400° C. | | 500° C. | |
|---|---|---|---|---|---|---|---|---|---|---|
| to interface | Cu | Si | Cu | Si | Cu | Si | Cu | Si | Cu | Si |
| (μm) | (%) | (%) | (%) | (%) | (%) | (%) | (%) | (%) | (%) | (%) |
| −0.20 | 96 | 1 | 92 | 1 | 93 | 1 | 94 | 1 | 94 | 1 |
| −0.18 | 95 | 1 | 92 | 1 | 93 | 1 | 94 | 1 | 93 | 1 |
| −0.16 | 95 | 1 | 93 | 2 | 93 | 2 | 94 | 1 | 93 | 1 |
| −0.14 | 97 | 1 | 92 | 2 | 93 | 2 | 94 | 2 | 92 | 2 |
| −0.12 | 95 | 2 | 92 | 3 | 94 | 3 | 94 | 2 | 93 | 2 |
| −0.10 | 97 | 2 | 91 | 3 | 93 | 3 | 94 | 3 | 93 | 3 |
| −0.08 | 95 | 3 | 91 | 3 | 93 | 5 | 93 | 6 | 93 | 2 |
| −0.06 | 95 | 5 | 91 | 4 | 92 | 8 | 91 | 9 | 91 | 5 |
| −0.05 | 92 | 8 | 88 | 5 | 88 | 12 | 89 | 11 | 88 | 11 |
| −0.04 | 86 | 14 | 83 | 10 | 84 | 16 | 85 | 15 | 82 | 14 |
| −0.035 | 83 | 17 | 80 | 12 | 81 | 19 | 82 | 18 | 77 | 20 |
| −0.03 | 80 | 20 | 76 | 17 | 78 | 22 | 78 | 22 | 73 | 24 |
| −0.025 | 77 | 23 | 70 | 22 | 73 | 27 | 73 | 27 | 70 | 29 |
| −0.02 | 72 | 28 | 68 | 28 | 68 | 31 | 66 | 30 | 66 | 33 |
| −0.015 | 68 | 32 | 64 | 32 | 63 | 35 | 63 | 34 | 62 | 38 |
| −0.01 | 60 | 40 | 59 | 37 | 58 | 40 | 56 | 38 | 56 | 40 |
| −0.005 | 55 | 45 | 53 | 42 | 52 | 44 | 53 | 43 | 52 | 44 |
| 0 | 50 | 50 | 47 | 47 | 49 | 49 | 48 | 48 | 48 | 48 |
| 0.005 | 45 | 55 | 43 | 51 | 44 | 55 | 46 | 53 | 44 | 52 |
| 0.01 | 38 | 62 | 38 | 55 | 39 | 58 | 39 | 61 | 38 | 58 |
| 0.015 | 34 | 66 | 34 | 60 | 34 | 63 | 35 | 64 | 34 | 60 |
| 0.02 | 30 | 70 | 29 | 65 | 30 | 70 | 30 | 66 | 31 | 65 |
| 0.025 | 26 | 74 | 24 | 68 | 27 | 73 | 26 | 71 | 28 | 69 |
| 0.03 | 22 | 78 | 22 | 72 | 23 | 77 | 23 | 76 | 24 | 73 |
| 0.035 | 18 | 82 | 18 | 76 | 21 | 79 | 20 | 79 | 20 | 77 |
| 0.04 | 15 | 85 | 15 | 79 | 18 | 82 | 17 | 81 | 18 | 79 |
| 0.05 | 12 | 88 | 12 | 84 | 13 | 87 | 12 | 83 | 12 | 84 |
| 0.06 | 9 | 91 | 9 | 88 | 11 | 89 | 10 | 89 | 9 | 90 |
| 0.08 | 5 | 95 | 3 | 93 | 5 | 95 | 6 | 94 | 5 | 92 |
| 0.10 | 3 | 97 | 1 | 95 | 3 | 97 | 3 | 97 | 4 | 96 |
| 0.12 | 1 | 99 | 1 | 98 | 2 | 98 | 2 | 98 | 3 | 97 |
| 0.16 | 1 | 99 | 1 | 99 | 1 | 99 | 0 | 99 | 2 | 98 |
| 0.20 | 1 | 99 | 1 | 99 | 0 | 99 | 0 | 100 | 1 | 98 |

TABLE 2d
Cu—Ni Thin Film (Example 4).

| Distance | Pre-anneal | | 250° C. | | 400° C. | | 500° C. | |
|---|---|---|---|---|---|---|---|---|
| to interface | Cu | Si | Cu | Si | Cu | Si | Cu | Si |
| (μm) | (%) | (%) | (%) | (%) | (%) | (%) | (%) | (%) |
| −0.20 | 98 | 2 | 98 | 2 | 97 | 2 | 95 | 5 |
| −0.18 | 98 | 2 | 98 | 2 | 97 | 3 | 94 | 6 |
| −0.16 | 98 | 2 | 98 | 2 | 97 | 3 | 93 | 5 |
| −0.14 | 97 | 3 | 98 | 2 | 97 | 3 | 93 | 6 |
| −0.12 | 97 | 2 | 98 | 2 | 97 | 2 | 91 | 7 |
| −0.10 | 97 | 3 | 97 | 3 | 97 | 3 | 90 | 8 |
| −0.08 | 98 | 2 | 98 | 3 | 96 | 4 | 85 | 12 |
| −0.06 | 96 | 4 | 92 | 8 | 90 | 8 | 80 | 17 |
| −0.05 | 94 | 5 | 88 | 12 | 86 | 12 | 75 | 23 |
| −0.04 | 87 | 13 | 84 | 16 | 82 | 18 | 71 | 25 |
| −0.035 | 82 | 18 | 79 | 21 | 78 | 22 | 68 | 29 |
| −0.03 | 75 | 25 | 75 | 25 | 75 | 25 | 66 | 33 |
| −0.025 | 70 | 30 | 71 | 29 | 71 | 28 | 63 | 36 |
| −0.02 | 64 | 36 | 66 | 34 | 68 | 32 | 60 | 38 |
| −0.015 | 62 | 38 | 60 | 40 | 64 | 35 | 58 | 40 |
| −0.01 | 59 | 41 | 55 | 45 | 58 | 42 | 56 | 42 |
| −0.005 | 53 | 47 | 51 | 49 | 54 | 46 | 53 | 45 |
| 0 | 50 | 50 | 50 | 50 | 50 | 50 | 50 | 50 |
| 0.005 | 46 | 54 | 47 | 53 | 48 | 52 | 46 | 52 |
| 0.01 | 41 | 58 | 42 | 58 | 45 | 55 | 44 | 54 |
| 0.015 | 38 | 60 | 37 | 63 | 40 | 60 | 42 | 56 |
| 0.02 | 33 | 64 | 33 | 67 | 37 | 63 | 39 | 59 |
| 0.025 | 29 | 68 | 30 | 70 | 35 | 65 | 38 | 61 |
| 0.03 | 26 | 71 | 27 | 73 | 32 | 68 | 37 | 63 |
| 0.035 | 23 | 75 | 25 | 75 | 30 | 70 | 35 | 64 |
| 0.04 | 20 | 78 | 20 | 80 | 27 | 73 | 34 | 66 |
| 0.05 | 14 | 85 | 17 | 83 | 24 | 76 | 31 | 68 |
| 0.06 | 12 | 88 | 15 | 84 | 21 | 78 | 29 | 71 |
| 0.08 | 8 | 92 | 10 | 90 | 15 | 85 | 24 | 76 |
| 0.10 | 5 | 95 | 8 | 92 | 12 | 88 | 22 | 78 |
| 0.12 | 3 | 97 | 6 | 94 | 10 | 90 | 20 | 80 |
| 0.16 | 2 | 98 | 4 | 96 | 8 | 92 | 16 | 84 |
| 0.20 | 1 | 99 | 2 | 98 | 5 | 95 | 14 | 86 |

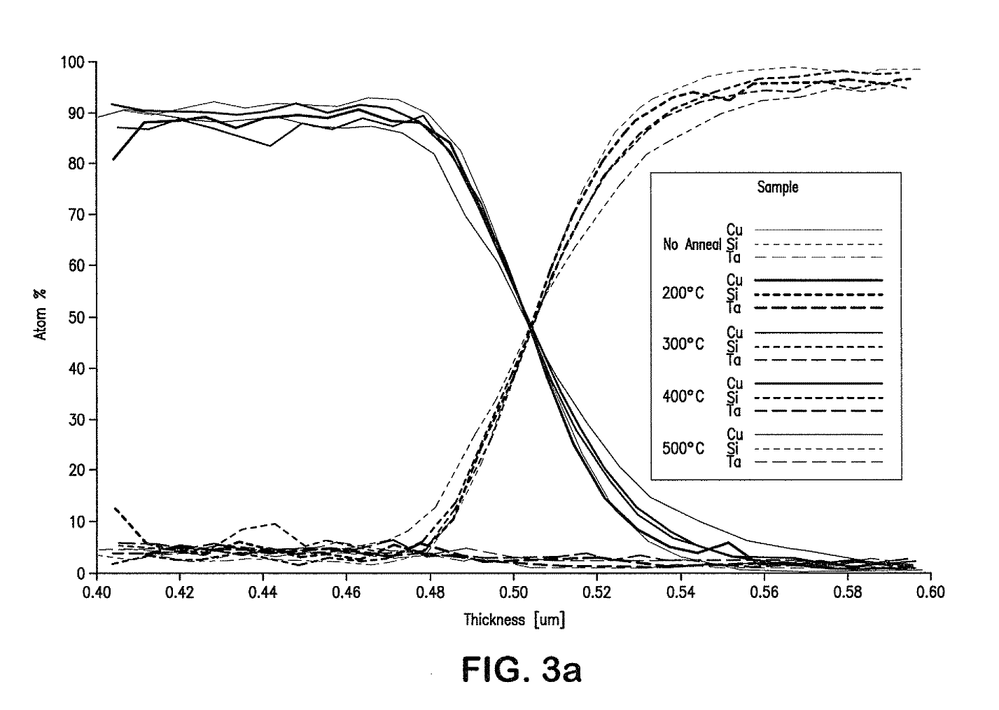

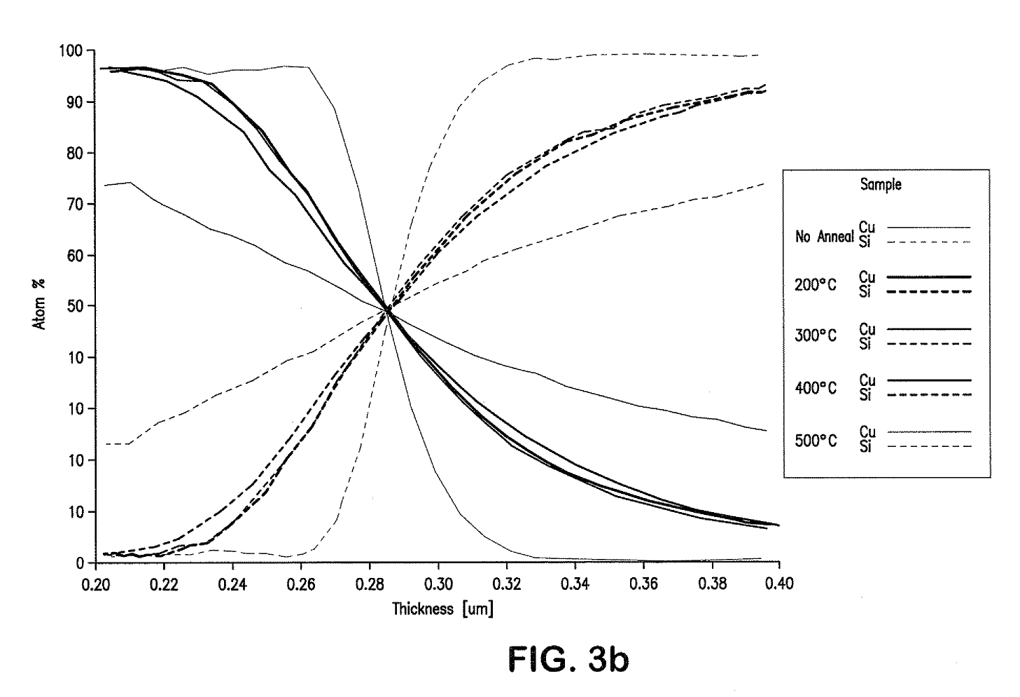

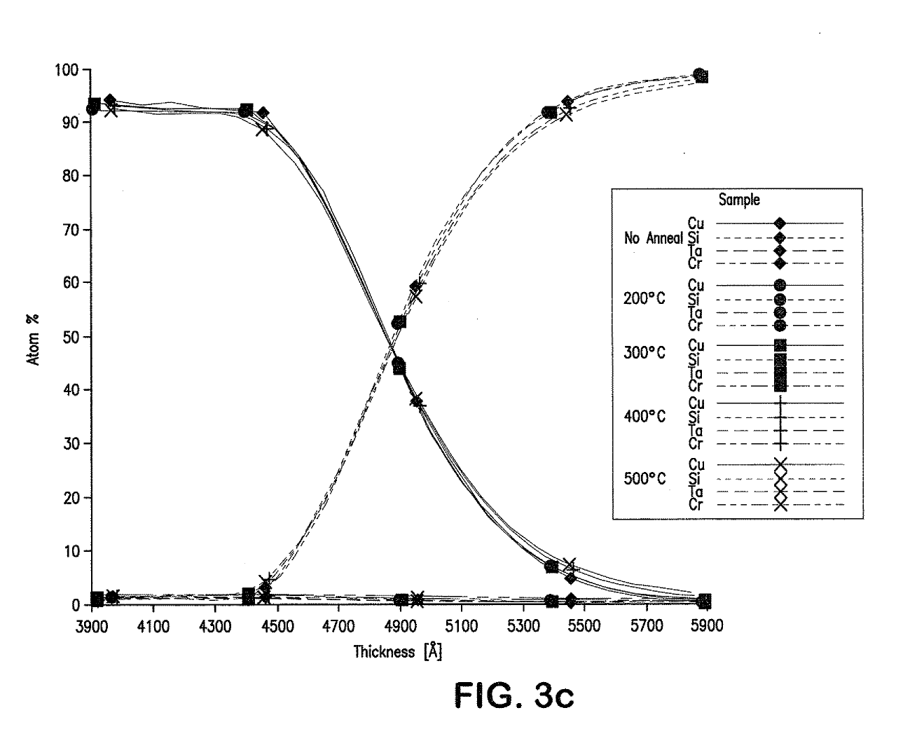

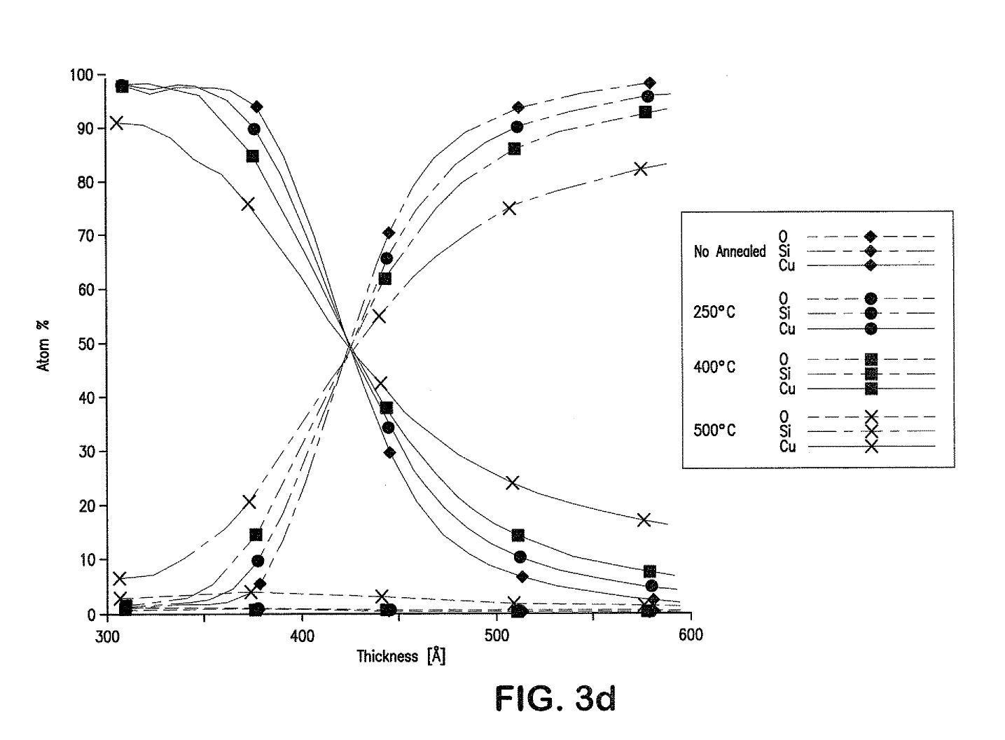

Overlays of the AES spectra for Example 1, the Control Sample, and Example 3 prior to annealing and at each tested temperature are shown in FIGS. 3a, 3b and 3c, respectively. As shown in FIGS. 3a and 3c, the interface of the silicon substrate and the Cu—Ta and Cu—Ta/Cr films do not noticeably change upon annealing, even at temperatures up to 500° C. FIG. 3b shows that the Cu/Si interface for a pure copper film deposited on a silicon substrate undergoes significant mutual diffusion even at relatively low annealing temperatures. Accordingly, the Cu—Ta film of Example 1 and the Cu—Ta/Cr film of Example 3 can be used directly on silicon substrates without the need for a barrier layer to protect against diffusion. As shown in FIG. 3d, the interface of the silicon substrate and the Cu—Ni film does not change upon annealing, even at temperatures up to 500° C., as significantly as the interface in the Control Example and Comparative Examples.

As shown below in Table 3a, diffusion of Cu and Si in the Cu—Mo film of Comparative Example 5 is significant after annealing at only 225° C. for 2 hours. Diffusion in the Cu—Mo film of Comparative Example 5 is severe after annealing at 530° C.

TABLE 3a
Cu—Mo Thin Film (Comparative Example 5).

| Distance | 225° C. | | 400° C. | | 530° C. | |
|---|---|---|---|---|---|---|
| to Interface | Cu | Si | Cu | Si | Cu | Si |
| (μm) | (%) | (%) | (%) | (%) | (%) | (%) |
| −0.40 | 87 | 4 | 77 | 8 | 71 | 16 |
| −0.36 | 90 | 4 | 81 | 8 | 76 | 10 |
| −0.32 | 91 | 4 | 82 | 7 | 78 | 8 |
| −0.28 | 90 | 4 | 82 | 7 | 79 | 12 |
| −0.24 | 93 | 6 | 86 | 5 | 79 | 8 |
| −0.20 | 90 | 7 | 86 | 7 | 77 | 12 |
| −0.16 | 88 | 8 | 86 | 7 | 74 | 16 |
| −0.12 | 85 | 11 | 85 | 9 | 71 | 21 |
| −0.10 | 80 | 15 | 82 | 13 | 67 | 25 |
| −0.08 | 77 | 20 | 80 | 16 | 64 | 28 |
| −0.07 | 74 | 22 | 76 | 20 | 62 | 30 |
| −0.06 | 72 | 25 | 72 | 24 | 59 | 33 |
| −0.05 | 70 | 28 | 67 | 29 | 58 | 37 |
| −0.04 | 65 | 32 | 62 | 32 | 54 | 39 |
| −0.03 | 61 | 35 | 58 | 36 | 52 | 41 |
| −0.02 | 58 | 40 | 55 | 40 | 51 | 42 |
| −0.01 | 54 | 43 | 51 | 45 | 49 | 45 |
| 0 | 48 | 48 | 47 | 47 | 47 | 47 |
| 0.01 | 45 | 51 | 46 | 50 | 45 | 50 |
| 0.02 | 43 | 54 | 44 | 52 | 43 | 51 |
| 0.03 | 40 | 58 | 42 | 55 | 42 | 52 |
| 0.04 | 38 | 62 | 41 | 56 | 41 | 54 |
| 0.05 | 36 | 63 | 40 | 58 | 41 | 55 |
| 0.06 | 34 | 64 | 38 | 59 | 40 | 56 |
| 0.07 | 32 | 67 | 37 | 60 | 40 | 57 |
| 0.08 | 31 | 68 | 36 | 61 | 39 | 58 |
| 0.10 | 29 | 70 | 35 | 62 | 38 | 59 |
| 0.12 | 28 | 72 | 34 | 63 | 37 | 60 |
| 0.16 | 25 | 73 | 33 | 64 | 36 | 61 |
| 0.20 | 24 | 76 | 32 | 66 | 35 | 62 |
| 0.24 | 23 | 77 | 32 | 66 | 35 | 63 |
| 0.32 | 21 | 79 | 30 | 68 | 34 | 64 |

A further increase in interface width after annealing indicates more diffusion after annealing, as shown in Table 4 below. The data clearly shows that Cu—Ta, Cu—Cr and Cu—Ta/Cr films have much less diffusion than pure Cu and Cu—Mo films.

TABLE 4
Interface Width of Pure Cu and Cu-Refractory Metal Films on Si
Substrate as Function of Annealing Temperature

| anneal temp | pure Cu | Cu—Ta | Cu—Cr | Cu—TaCr | Cu—Mo |
|---|---|---|---|---|---|
| (° C.) | (nm) | (nm) | (nm) | (nm) | (nm) |
| as deposit | 50 | 50 | 63 | 68 | |
| 200° C. | 120 | 53 | 66 | 70 | 140 @ 225° C. |
| 300° C. | 125 | 60 | 70 | 72 | |
| 400° C. | 135 | 64 | 68 | 72 | >140 |
| 500° C. | 340 | 66 | 70 | 75 | >240 @ 530° C. |

The resistivity of the Cu—Ta film of Example 1 as deposited (pre-anneal) is quite low, similar to both the pure Cu film of the Control Sample and the Cu—Mo film of Comparative Example 5. The Cu—Ta film resistivity is much lower than the Cu—W film of Comparative Example 6. The resistivity of the Cu—Ta film even decreases slightly after annealing at 600° C., indicating that the inventive films are thermally stable with no oxidation and/or structural changes. Accordingly, the resistivity and thermal annealing behavior of the inventive films is superior to that of both the Cu—Mo and Cu—W films of Comparative Examples 5 and 6. The inventive films are thus highly suitable for conducting wire and electrodes applications in flat panel display and semiconductor IC's. The resistivity of the pure Cu film decreases slightly after annealing to 400° C., but sharply increases to an unacceptable value after annealing at 500° C., likely due to phase segregation. The resistivity of the Cu—Mo film increases after annealing at 400° C. The resistivity of the Cu—W film, as deposited, is higher than pure Cu, Cu—Ta and Cu—Mo films (almost double) and increases significantly after annealing at 400° C. The comparative resistivity behavior evidences the superior thermal stability of Cu—Ta over Cu—Mo, Cu—W and pure Cu.

As shown below in Table 5, the resistivity of the Cu—Ta, Cu—TaCr, Cu—Mo and Cu—W films are compared with pure Cu films, Cu—Ta, Cu—TaCr, and Cu—Mo films are thermally stable up to 500° C. However, as discussed above, Cu—Mo does not adequately prevent diffusion. Pure Cu, Cu—TaSi and Cu—W films are not thermally stable, as indicated by their resistivity increasing significantly after annealing at temperatures of 400°-500° C. This comparison is depicted graphically in FIG. 5.

TABLE 5

| Anneal | | | | | | | |
|---|---|---|---|---|---|---|---|
| Temp (° C.) | Cu | Cu—Ta | Cu—TaCr | Cu—Ni | Cu—Mo | Cu—W | Cu—TaSi |
| Pre-anneal | 5.31 | 5.86 | 6.04 | 4.55 | 5.58 | 11.8 | 6.18 |
| 200 | 2.78 | 5.45 | 5.53 | 2.85 | | 11.1 | 5.35 |
| 300 | 2.67 | 4.90 | 5.63 | 2.85 | 5.25 | 10.2 | 9.36 |
| 400 | 2.67 | 4.26 | 4.71 | 3.90 | 6.05 | 17.5 | 15.2 |
| 500 | 50.38 | 4.52 | 4.67 | 9.85 | 6.15 | 17.7 | |
| 600 | | 4.57 | | | | | |

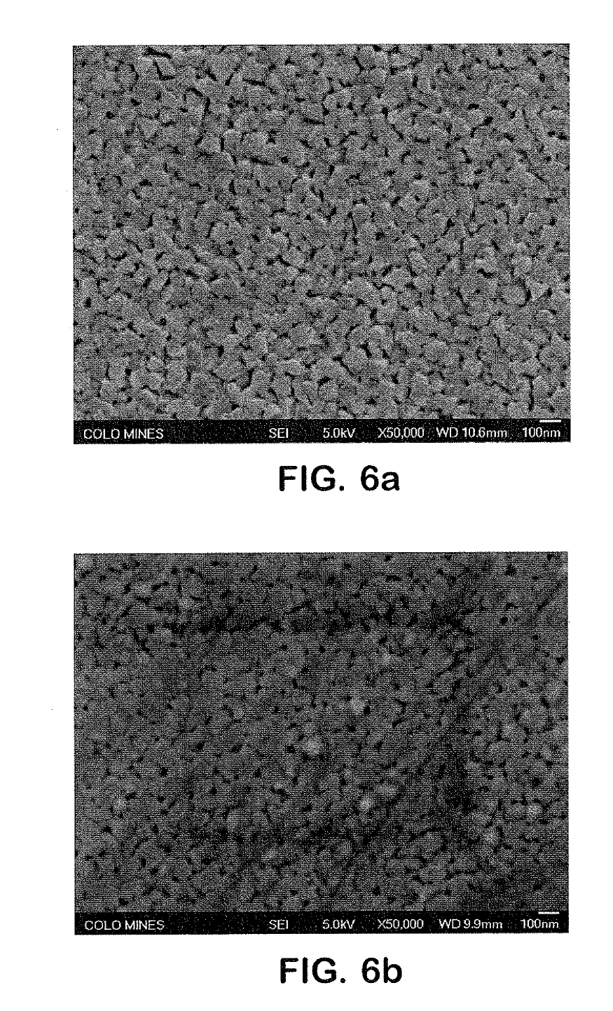

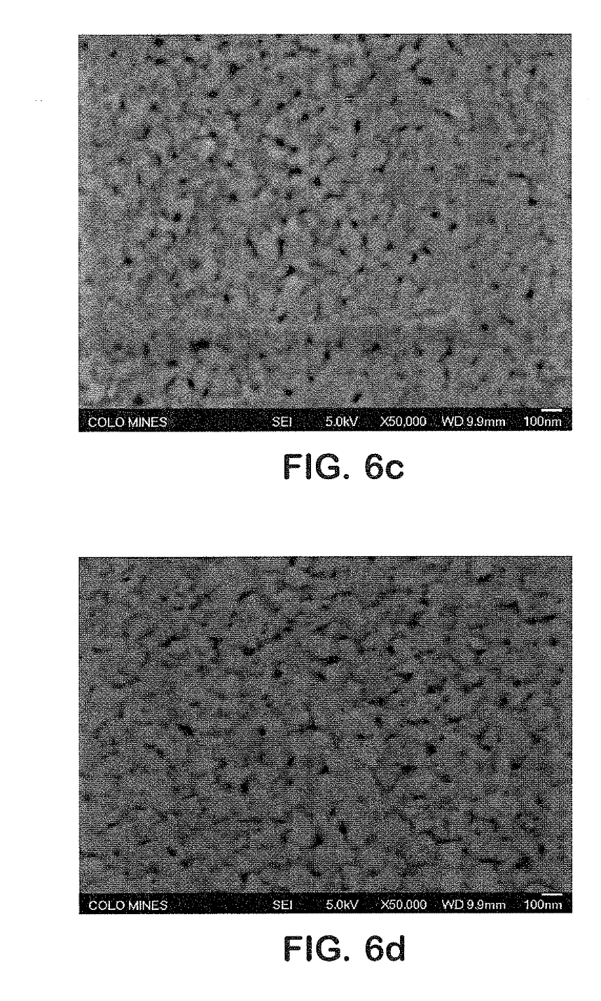

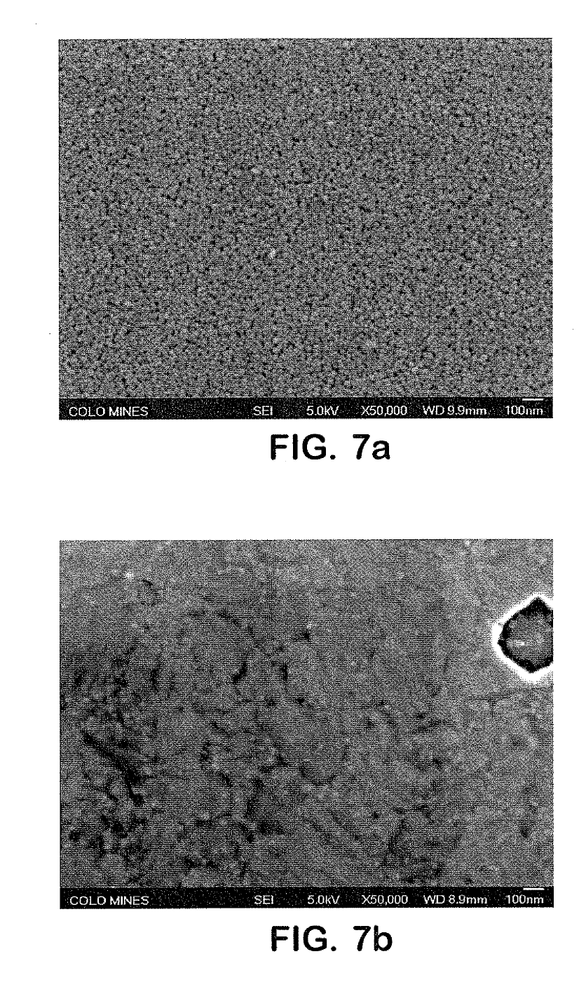

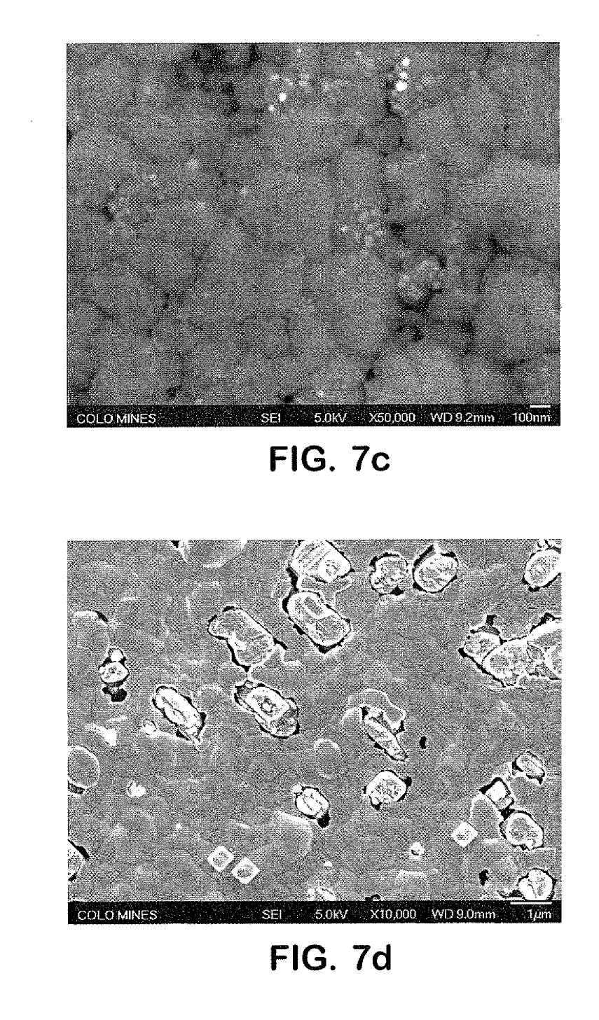

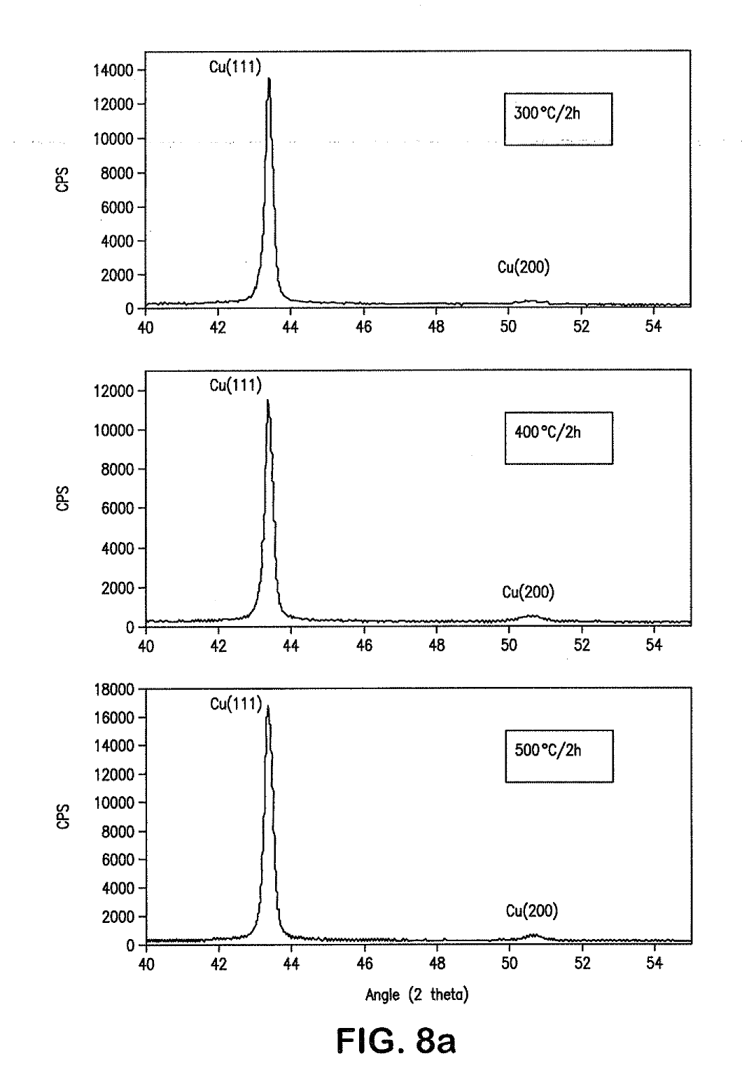

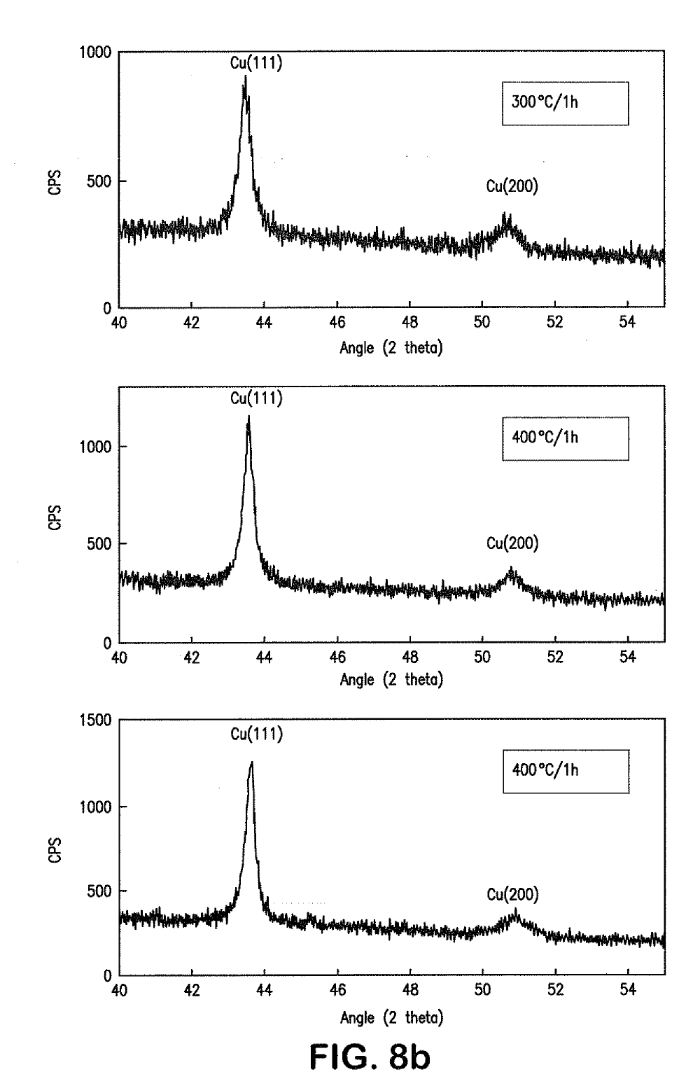

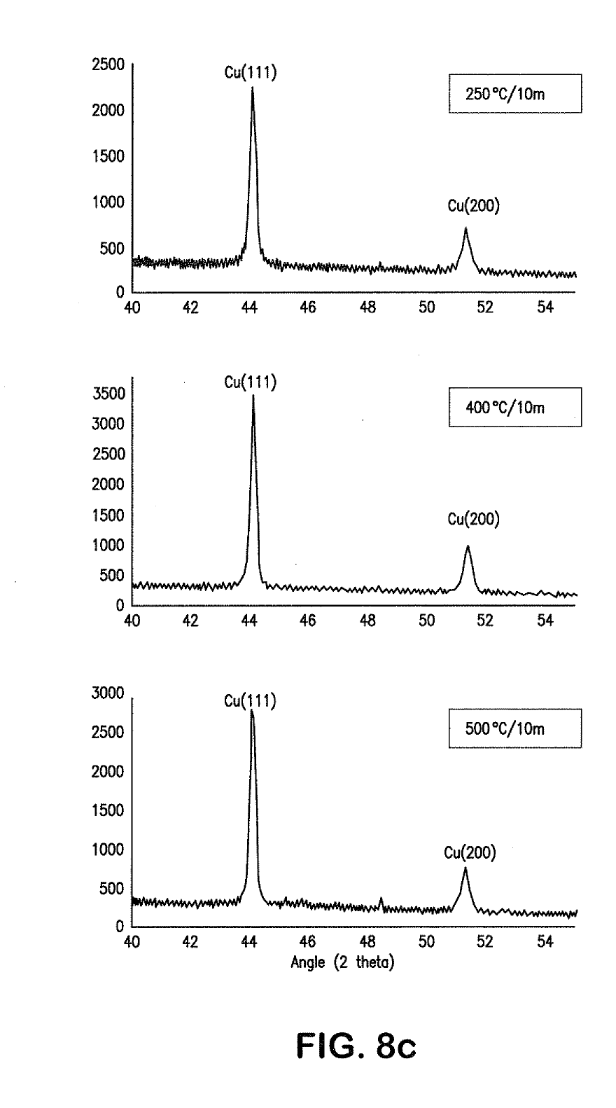

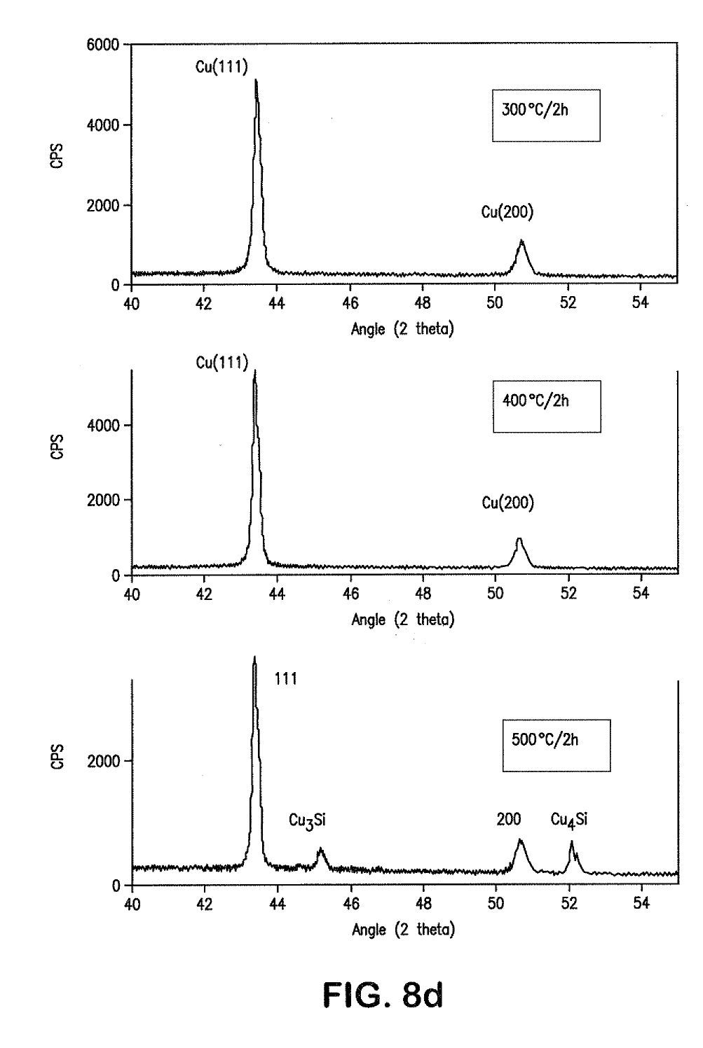

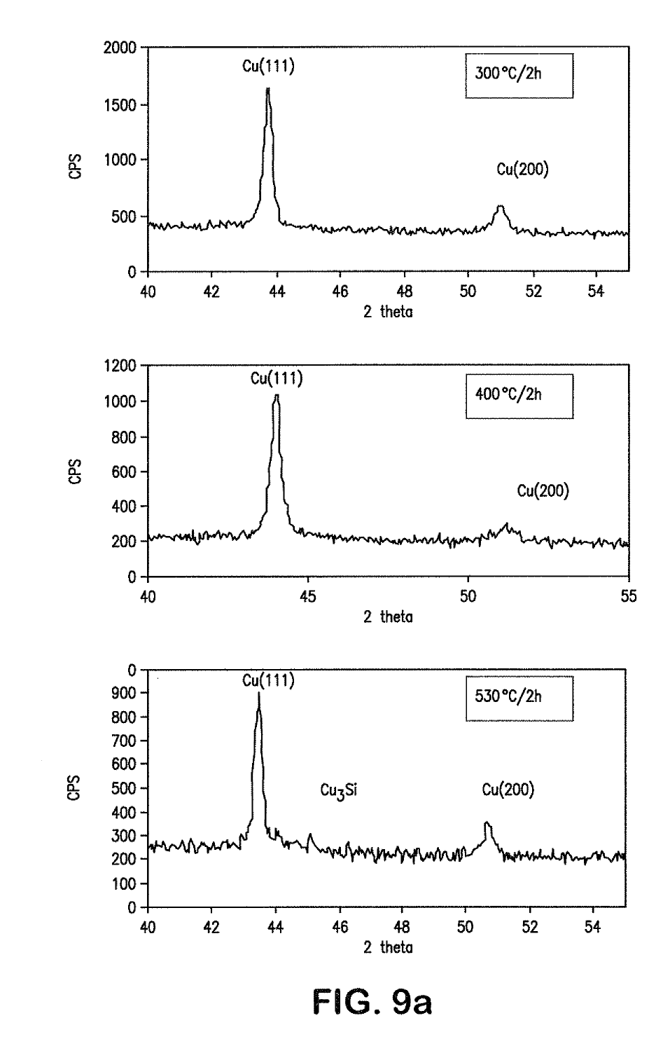

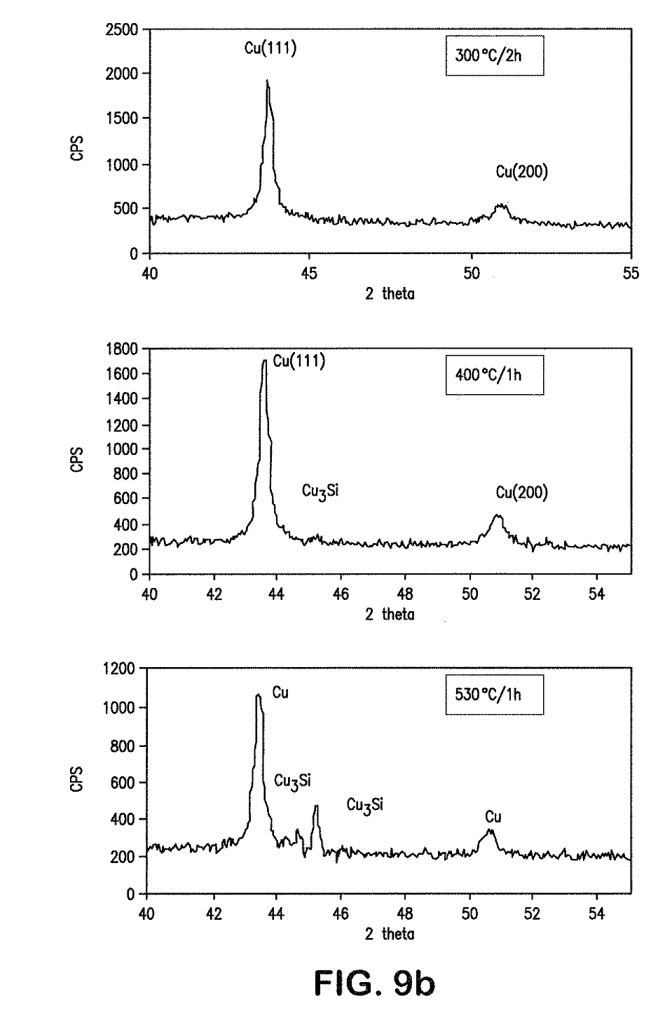

The Cu—Ta thin film of Example 1 exhibits a nanocrystalline microstructure with average grain size about 80 nm, as detected by SEM imaging. The average grain size of the Cu—Ta film was almost unchanged after annealing up to 500° C. for 2 hours, as shown in FIGS. 6a-6d. The pure Cu film of the Control sample, as deposited, had nanocrystalline structure with a small average grain size of about 20 nm. However, recrystallization began at as low as 200° C. and grain size began to increase substantially. The average grain size of the pure Cu film increased to 0.4 μm and the film surface color changed to dark after annealing at 400° C. for 2 hours, evidencing film microstructure change from nanocrystalline to polycrystalline. As shown in FIGS. 7a-7d, the pure Cu film, as deposited, had a nanocrystalline structure with an average grain size of about 20 nm (FIG. 7a), with recrystallization starting at as low as 200° C. and 300° C. annealing temperatures with grain size increasing substantially (FIG. 7b). The pure Cu film grain size increased to 0.4 μm after annealing at 400° C. for 2 hours, and changed from nanocrystalline to polycrystalline (FIG. 7c). Additionally, as shown in FIG. 7d, the pure Cu film showed phase segregation and Cu-silicide formation (Cu₃Si and Cu₄Si) after annealing at 500° C. for 2 hours.

Cu-silicide phase formation can also be detected by X-ray diffraction. The Cu—Ta film of Example 1 did not exhibit Cu-silicide formation after annealing up to 500° C. for 2 hours. This reiterates that Cu and Si mutual diffusion is negligible between Cu—Ta films and the Si substrate at high temperatures. The XRD peaks of the Cu—Ta film did not change after annealing which indicates no change in the Cu—Ta crystal structure. The pure Cu film underwent silicide (Cu₃Si and Cu₄Si) formation after annealing at 500° C. for 2 hours. This indicates that Cu and Si mutual diffusion is significantly high between pure Cu films and the Si substrate at high temperatures. FIGS. 8a, 8b, 8c and 8d show the XRD spectra of the Cu—Ta film of Example 1, the Cu—Ta/Cr film of Example 3, the Cu—Ni film of Example 4, and the Cu film of the Control Sample, respectively. Cu—Ta film thermal diffusion behavior is also better than Cu—Mo films and Cu—W films, Cu—Mo films exhibited silicide formation after annealing at 530° C. for 1 hour. Cu—W films exhibited silicide formation after annealing at 400° C. for 1 hour. FIGS. 9a and 9b show the XRD spectra of the Cu—Mo film of Comparative Example 5 and the Cu—W film of Comparative Example 6, respectively.

A comparison of various properties of pure Cu, Cu—Ta, Cu—Cr, Cu—Mo and Cu—W films (as deposited) is shown below in Table 6. Most properties of Cu—Ta films are similar to pure Cu, Cu—Mo and Cu—W films, except that Cu—Ta films exhibit superior thermal stability and do not suffer from diffusion during high temperature processing. Cu—Ta films have a low resistivity similar to pure Cu films and Cu—Mo films, which is lower than Cu—W films. Cu—Ta has an acceptable sputtering deposition rate similar to Cu, Cu—Mo and Cu—W films. Cu—Ta films have a high wet-etch rate (in solution HNO₃:H₂O=3:1), which is higher than pure Cu films and lower than Cu—Mo and Cu—W films, but still within an acceptable range. Cu—Ta films have a similar adhesion to Corning 1737 glass substrate as that of pure Cu, Cu—Mo and Cu—W films.

TABLE 6
Properties of Cu-refractory Metal and Pure Cu Films

| | | | | | | Cu—Mo | Cu—W | CuTaSi |
|---|---|---|---|---|---|---|---|---|
| | | Cu—Ta | Cu—Cr | Cu—TaCr | Cu—Ni | (1.1 wt. %) | (5 wt. %) | (2%100 ppm) |
| | pure Cu | (2.5 wt. %) | (2.0 wt %) | (2%1%) | (1.2 wt %) | Comp. | Comp. | Comp. |
| Film | Control | Example 1 | Example 2 | Example 3 | Example 4 | Example 5 | Example 6 | Example 7 |
| Cu/Si mutual | 200° C. | >500° C. | >500° C. | >500° C. | 400° C. | 225° C. | >500° C. | 300° C. |
| diffusion Temp. | | | | | | | | |
| resistivity-avg | 5.31 | 5.86 | 8.72 | 6.04 | 4.55 | 5.58 | 11.8 | 6.18 |
| (μΩ · cm) | | | | | | | | |
| resistivity-best | 2.67 | 4.26 | 7.51 | 4.67 | 2.85 | 5.25 | 8.19 | 5.35 |
| (μΩ · cm) | | | | | | | | |
| deposition rate | 1.25 | 1.00 | 0.79 | 0.87 | 1.17 | 1.22 | 1.16 | 1.03 |
| (nm/s) | | | | | | | | |
| etch rate | 120 | 180 | 6.2 | 8.2 | 7.2 | 270 | 280 | 7.6 |
| (nm/s) | | | | | | | | |
| adhesion to | 0B, poor | 0B, poor | 5B, good | 5B, good | 5B, good | 5B, good | 0B, poor | 0B, poor |
| 1737 glass | | | | | | | | |
| Microstructure, | nano- | nano- | nano- | nano- | nano- | granular with | granular with | nano- |
| Grain size (nm) | crystalline, | crystalline, | crystalline, | crystalline, | crystalline, | hillocks | hillocks | crystalline, |
| | 20 | 80 | 30 | 30-90 | 40 | | | 40 |

The thermally stable nanocrystalline structure of Cu—Ta and Cu—Cr films according to various embodiments of the present invention is superior to that of Cu—Mo and Cu—W films which can develop granular structures with many hillocks and other defects in the films after thermal treatment.

In addition, Cu—Cr, Cu—Ta/Cr, and Cu—Ni films according to various embodiments of the present invention have much improved adhesion to Corning 1737 glass substrate (with designated adhesion number 5B), compared to pure Cu, Cu—Ta, Cu—Mo and Cu—W films (all with adhesion number 0B). By ASTM standard (D3359-02 and B905-00), a tape test method classifies adhesion into 5 levels (0B to 5B). The higher the number, the better the adhesion, Cu—Cr, Cu—Ta/Cr, and Cu—Ni films according to various embodiments of the present invention also have much lower etch rate (e.g., 6.2 nm/s for Cu—Cr film) than other Cu alloy films, which enables etch processes to be better controlled. Thermal stability examination of Cu—Cr thin films according to various embodiments of the present invention show excellent performance in that regard as well. SEM analysis showed nano-sized grains without perceivable grain growth. Auger profile analysis showed no mutual diffusion up to 500° C. X-ray diffraction analysis showed no silicide formation up to 400° C., but did show some Cu₄Si formation after 500° C. annealing.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

What is claimed is:

1. A metallic material consisting essentially of a conductive metal matrix and a refractory dopant component selected from the group consisting of tantalum, chromium, rhodium, ruthenium, iridium, osmium, platinum, rhenium, niobium, hafnium and mixtures thereof.

2. The metallic material according to claim 1, wherein the refractory dopant component is present in an amount of 0.1 to 6 percent by weight, based on the metallic material.

3. The metallic material according to claim 1, wherein the refractory dopant component is present in an amount of 1 to 3 percent by weight, based on the metallic material.

4. The metallic material according to claim 1, wherein the conductive metal matrix comprises copper.

5. The metallic material according to claim 4, wherein the refractory dopant component comprises a metal selected from the group consisting of tantalum, chromium and combinations thereof.

6. The metallic material according to claim 5, wherein the refractory dopant component is present in an amount of 0.1 to 6 percent by weight, based on the metallic material.

7. The metallic material according to claim 5, wherein the refractory dopant component is present in an amount of 1 to 3 percent by weight, based on the metallic material.

8. The metallic material according to claim 4, wherein the refractory dopant comprises chromium and tantalum.

9. The metallic material according to claim 8, wherein the chromium and the tantalum are present in a combined amount of 0.1 to 6 percent by weight.

10. The metallic material according to claim 8, wherein the chromium and the tantalum are present in a combined amount of 1 to 3 percent by weight.

11. The metallic material according to claim 8, wherein the chromium is present in an amount of about 1 percent by weight, and the tantalum is present in an amount of about 2 percent by weight.

12. A metallic material consisting essentially of copper and a dopant component selected from the group consisting of titanium and nickel.

13. A sputtering target prepared by a process comprising:
(a) providing a homogenous powder mixture consisting essentially of a metallic copper powder and a refractory metal powder selected from the group of powders consisting of tantalum, chromium, rhodium, ruthenium, iridium, osmium, platinum, rhenium, niobium, hafnium and mixtures thereof;
(b) subjecting the homogenous powder mixture to a thermo-mechanical method to form a sputtering target plate.

14. The sputtering target according to claim 13, wherein the thermo-mechanical method comprises pressing and sintering.

15. The sputtering target according to claim 13, wherein the thermo-mechanical method comprises hot isostatic pressing.

16. The sputtering target according to claim 15, wherein the hot isostatic pressing comprises densification under about 69 MPa at about 750° C. for about 4 hours.

17. The sputtering target according to claim 15, wherein the thermo-mechanical method further comprises compacting and sintering prior to hot isostatic pressing.

18. The sputtering target according to claim 13, wherein the refractory metal powder is present in an amount of 0.1 to 6 percent by weight, based on the powder mixture.

19. The sputtering target according to claim 18, wherein the refractory metal powder comprises a metal selected from the group consisting of tantalum, chromium and mixtures thereof.

20. The sputtering target according to claim 15, wherein the refractory metal powder is present in an amount of 0.1 to 6 percent by weight, based on the powder mixture.

21. A sputtering target comprising a densified, homogenous powder mixture consisting essentially of a metallic copper powder and a refractory metal powder selected from the group of metal powders consisting of tantalum, chromium, rhodium, ruthenium, iridium, osmium, platinum, rhenium, niobium, hafnium and mixtures thereof.

22. The sputtering target according to claim 21, wherein the refractory metal powder comprises a metal selected from the group consisting of tantalum, chromium and mixtures thereof.

23. The sputtering target according to claim 22, wherein the refractory metal powder is present in an amount of about 0.1 to 6 percent by weight, based on the powder mixture.

24. A method comprising:
(a) providing a substrate;
(b) providing a sputtering target prepared by the process according to claim 13; and
(c) subjecting the sputtering target to a source of energy such that a thin film comprised of the sputtering target material is disposed on a surface of the substrate.

25. A method comprising:
(a) providing a substrate;
(b) providing a sputtering target according to claim 21; and
(c) subjecting the sputtering target to a source of energy such that a thin film comprised of the sputtering target material is disposed on a surface of the substrate.

26. The method according to claim 25, wherein subjecting the target to a source of energy comprises physical vapor deposition.

27. The method according to claim 25, wherein physical vapor deposition comprises DC magnetron sputtering.

28. The method according to claim 27, wherein the DC magnetron sputtering is carried out using an argon-containing plasma at a power of about 100 to 2000 watts, a pressure of about 1 to 20 mTorr, a substrate temperature of about room temperature to 500° C., and at a substrate bias of about 0 to −300V.

29. A thin film prepared by the method according to claim 24.

30. A thin film prepared by the method according to claim 25.

31. A thin film consisting essentially of copper and a refractory metal dopant selected from the group consisting of tantalum, chromium, rhodium, ruthenium, iridium, osmium, platinum, rhenium, niobium, hafnium and mixtures thereof, and having a thermally stable nanocrystalline structure.

32. A device comprising a substrate and a thin film disposed on a surface of the substrate, wherein the thin film consists essentially of copper and a refractory dopant having a concentration of about 0.1 to 6 percent by weight based on the thin film, and wherein the refractory dopant comprises a metal selected from the group consisting of tantalum, chromium, rhodium, ruthenium, iridium, osmium, platinum, rhenium, niobium, hafnium and mixtures thereof.
